(19) United States
(12) Patent Application Publication
(10) Pub. No.: US 2026/0171751 A1
(43) Pub. Date: Jun. 18, 2026

(54) LIGHT SOURCE SYSTEM AND LASER PROJECTION DEVICE

(71) Applicant: HISENSE LASER DISPLAY CO., LTD, Qingdao (CN)

(72) Inventors: Xigang ZHANG, Qingdao (CN); Yishi ZHAO, Qingdao (CN)

(21) Appl. No.: 19/462,320

(22) Filed: Jan. 28, 2026

Related U.S. Application Data
(63) Continuation of application No. PCT/CN2024/101624, filed on Jun. 26, 2024.

(30) Foreign Application Priority Data
Aug. 10, 2023 (CN) 202311006491.6
Dec. 28, 2023 (CN) 202311840869.2
Dec. 28, 2023 (CN) 202311840981.6

(51) Int. Cl. H01S 5/042; G03B 21/20

(52) U.S. Cl. CPC H01S 5/042; G03B 21/2033

(57) ABSTRACT

The present application provides a light source system and a laser projection device. The light source system comprises a display control circuit, a laser drive chip and a laser device module. The laser device module comprises at least one laser device. A drive signal output end of the display control circuit is connected to a drive signal receiving end of the laser drive chip. An enable signal output end of the display control circuit is connected to an enable signal receiving end of the laser drive chip. A drive current output end of the laser drive chip is connected to the laser device. The light source system can reduce the number of devices needing to be deployed in the light source system and can reduce a space occupied by the light source system, thereby improving the miniaturization and integration of the light source system.

### CROSS-REFERENCE TO RELATED APPLICATIONS

The present application is a continuation of International Application No. PCT/CN2024/101624, filed on Jun. 26, 2024, which claims priority to Chinese Patent Application No. 202311006491.6, filed on Aug. 10, 2023, Chinese Patent Application No. 202311840869.2, filed on Dec. 28, 2023, and Chinese Patent Application No. 202311840981.6, filed on Dec. 28, 2023. The entire disclosures of the above-identified applications are hereby incorporated herein by reference.

### TECHNICAL FIELD

The present application relates to the technical field of photoelectricity, and particularly to a light source system and a laser projection device.

### BACKGROUND

With the development of projection technology, laser projection devices such as projectors and laser televisions have been increasingly applied.

However, laser projection devices in the related art require the deployment of a large number of components, resulting in a relatively large occupied space of the laser projection devices.

### SUMMARY

The embodiments of the present application provide a light source system and a laser projection device.

On one hand, an embodiment of the present application provides a light source system, comprising a display control circuit, a laser drive chip, and a laser device module; the laser device module comprises at least one laser device;
a drive signal output end of the display control circuit is connected to a drive signal receiving end of the laser drive chip, an enable signal output end of the display control circuit is connected to an enable signal receiving end of the laser drive chip, and a drive current output end of the laser drive chip is connected to the at least one laser device;
the display control circuit is configured to determine at least one channel of laser drive signal, and output the at least one channel of laser drive signal and at least one channel of first enable signal to the laser drive chip; the laser drive signal is used to represent the magnitude of a drive current corresponding to a target color displayed by the at least one laser device; and
the laser drive chip is configured to respond to the at least one channel of first enable signal, adjust the magnitude of the drive current based on the at least one channel of laser drive signal, and output the adjusted drive current to the at least one laser device, so as to turn on the at least one laser device.

On the other hand, an embodiment of the present application provides a laser projection device, comprising the light source system described in the present application.

### DESCRIPTION OF THE DRAWINGS

In order to more clearly describe the implementations in the embodiments of the present application or in the related art, the accompanying drawings for describing the embodiments or the related art will be briefly described below. Apparently, the accompanying drawings in the description below show some embodiments of the present application, and those of ordinary skill in the art may still derive other drawings from these accompanying drawings.

FIG. 1 is a schematic structural diagram of a laser projection device according to an embodiment of the present application;

FIG. 2 is a schematic diagram of the image display of the laser projection device according to an embodiment of the present application;

FIG. 3 is a schematic diagram of a circuit structure of a light source system in the related art;

FIG. 4 is a signal timing diagram of a light source system in the related art;

FIG. 5 is a schematic structural diagram of a light source system according to an embodiment of the present application;

FIG. 6 is a schematic structural diagram of another light source system according to an embodiment of the present application;

FIG. 7 is a timing diagram of a drive signal of a light source system in the related art;

FIG. 8 is a schematic structural diagram of yet another light source system according to an embodiment of the present application;

FIG. 9 is a schematic diagram of a circuit structure of a feedback compensation module according to an embodiment of the present application;

FIG. 10 is a schematic diagram of a circuit structure of a filtering unit according to an embodiment of the present application;

FIG. 11 is a schematic diagram of a circuit structure of a light source system according to an embodiment of the present application;

FIG. 12 is a schematic diagram of a circuit structure of another light source system according to an embodiment of the present application;

FIG. 13 is a schematic diagram of a circuit structure of yet another light source system according to an embodiment of the present application;

FIG. 14 is a timing diagram of a laser device feedback signal and a drive current according to an embodiment of the present application;

FIG. 15 is a schematic diagram of a circuit structure of parallel-connected laser devices in the related art;

FIG. 16 is a schematic diagram of a circuit structure of a common-cathode laser device in the related art;

FIG. 17 is a schematic diagram of a circuit structure of a common-anode laser device in the related art;

FIG. 18 is a schematic diagram of a circuit structure of parallel-connected common-anode laser devices in the related art;

FIG. 19 is a schematic diagram of a circuit structure of yet another light source system according to an embodiment of the present application;

FIG. 20 is a schematic diagram of a circuit structure of yet another light source system according to an embodiment of the present application;

FIG. 21 is a timing diagram of an enable signal, a PWM signal and a current according to an embodiment of the present application;

FIG. 22 is a schematic diagram of a circuit structure of yet another light source system according to an embodiment of the present application;

FIG. 23 is a schematic diagram of a circuit structure of yet another light source system according to an embodiment of the present application;

FIG. 24 is a schematic diagram of a circuit structure of yet another light source system according to an embodiment of the present application;

FIG. 25 is a schematic diagram of a circuit structure of multiple series-connected common-cathode tricolor laser devices according to an embodiment of the present application;

FIG. 26 is a schematic diagram of a circuit structure of multiple series-connected common-anode tricolor laser devices according to an embodiment of the present application;

FIG. 27 is a schematic diagram of a circuit structure of yet another light source system according to an embodiment of the present application;

FIG. 28 is a schematic diagram of a local circuit structure for driving a red sub-laser device according to an embodiment of the present application;

FIG. 29 is a schematic diagram of a local circuit structure for driving another red sub-laser device according to an embodiment of the present application;

FIG. 30 is a schematic diagram of a local circuit structure for driving yet another red sub-laser device according to an embodiment of the present application;

FIG. 31 is a flowchart of a light source system control method according to an embodiment of the present application;

FIG. 32 is a schematic diagram of a circuit structure of a tricolor laser device in the related art;

FIG. 33 is a schematic diagram of a circuit structure of a light source system in the related art;

FIG. 34 is a schematic diagram of a circuit structure of another light source system according to an embodiment of the present application;

FIG. 35 is a schematic diagram of a circuit structure of yet another light source system according to an embodiment of the present application;

FIG. 36 is a schematic diagram of a circuit structure of yet another light source system according to an embodiment of the present application;

FIG. 37 is a schematic diagram of a circuit structure of yet another light source system according to an embodiment of the present application;

FIG. 38 is a schematic diagram of a circuit structure of yet another light source system according to an embodiment of the present application;

FIG. 39 is a schematic diagram of a circuit structure of yet another light source system according to an embodiment of the present application;

FIG. 40 is a schematic structural diagram of a current regulation unit according to an embodiment of the present application;

FIG. 41 is a schematic structural diagram of another current regulation unit according to an embodiment of the present application;

FIG. 42 is a schematic structural diagram of yet another light source system according to an embodiment of the present application;

FIG. 43 is a schematic structural diagram of yet another light source system according to an embodiment of the present application.

### DETAILED DESCRIPTION OF EMBODIMENTS

To make the objectives, embodiments, and advantages of the present application clearer, the exemplary embodiments of the present application are described clearly and completely below with reference to the accompanying drawings of the exemplary embodiments of the present application.

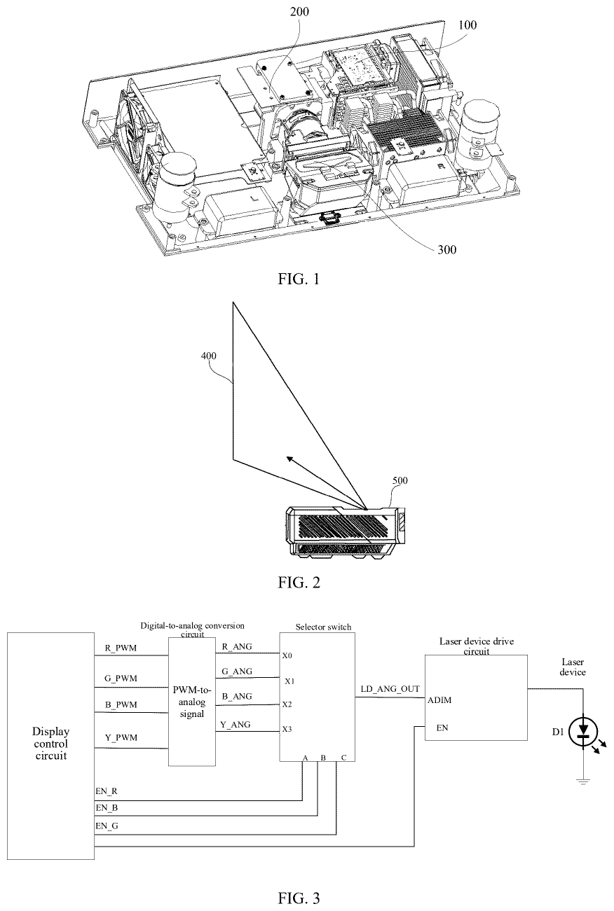

FIG. 1 is a schematic structural diagram of a laser projection device according to an embodiment of the present application, and FIG. 2 is a schematic diagram of image display of the laser projection device according to an embodiment of the present application. As shown in FIGS. 1 and 2, in some embodiments, after the upper housing of the laser projection device is disassembled, an internal structure, divided by optical functions, may include a light source system 100, an optical engine system 200 (also referred to as an optical engine or a light modulation device), and a lens system 300 (alternatively called a projection lens or a lens). The light source system 100 is configured to provide a light source illumination beam, which is transmitted to a rear-end optical engine system 200 and lens system 300; the lens system 300 projects the modulated laser beam onto a projection screen 400, thereby realizing image display. The light source system 100 may include laser devices of at least one color, for example, a blue laser device, or bicolor laser devices such as a blue laser device and a red laser device, or a tricolor laser light source including laser devices of three colors (red, green, and blue) for providing a tricolor laser illumination beam.

The laser beam provided by the light source system 100 enters the illumination optical path part of the optical engine system 200 after light combining and shaping. In a Digital Light Processing (DLP) projection architecture, a Digital Micro-mirror Device (DMD) chip is a core light modulation device. The DMD chip receives a drive control signal corresponding to an image signal, drives tens of thousands of tiny reflecting mirrors on a surface thereof to flip to a positive angle or a negative angle according to the corresponding drive signal, and reflects the light beam irradiating the surface into the lens system 300. The lens system 300 may be an ultra-short-throw projection lens configured to project the image beam onto a projection screen, thereby realizing projection image display. The laser projection device in the above example may be an ultra-short-throw laser projection device. As mentioned above, the light source system 100 of the laser projection device may include laser devices of at least one color. Taking the case where the light source system 100 includes laser devices of one color, such laser devices may also be referred to as monochromatic laser devices. Monochromatic laser devices are widely used due to advantages such as strong light intensity resistance, excellent color expression, and clear and transparent images.

Taking the monochromatic laser device being a blue laser device as an example, the light source of the monochromatic laser device may include a blue laser device, a phosphor wheel, and a color filter wheel. The blue laser device emits blue light that irradiates the phosphor wheel to excite wide-spectrum fluorescence, which is then filtered through the color filter wheel to generate red light and green light. Subsequently, the blue light can be projected through the transmission area of the color filter wheel, resulting in a three-primary-color light source (red, green, and blue). When the laser projection device displays images, the different brightness levels of the three colors (red, green, and blue) can be achieved by promptly adjusting the brightness of the blue laser device when the phosphor wheel and the color filter wheel rotate to correspond to different colors. The brightness of the laser device is determined by the magnitude of the drive current input to the laser device. Therefore, a laser driving solution with high precision and timely response is particularly important.

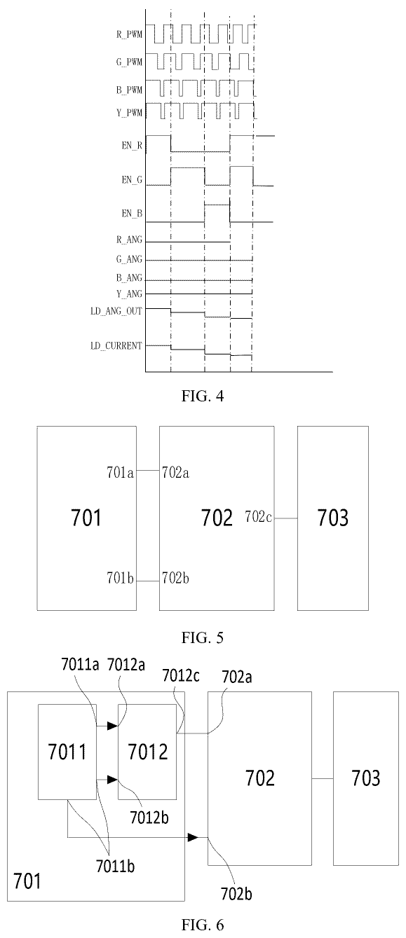

FIG. 3 is a schematic structural diagram of a light source system in the related art. As shown in FIG. 3, the light source system may include a display control circuit, a digital-to-analog conversion circuit, a selector switch, a laser device drive circuit, and a laser device. The display control circuit is configured to perform format conversion on an input video signal and output the format-converted signal to a DMD. In addition, the display control circuit may also output signals to control the rotation and synchronization of the color filter wheel and the phosphor wheel, and generate PWM control signals corresponding to current values for colors such as red, green, blue, and yellow based on a frame synchronization signal. The duty cycle of the PWM control signal may represent the current magnitude. For example, when the duty cycle is 100%, it represents a maximum current value. Based on the light source system shown in FIG. 3, FIG. 4 is a signal timing diagram of a light source system in the related art. As shown in FIGS. 3 and 4, Y_PWM, R_PWM, G_PWM, and B_PWM signals respectively represent the current values for yellow, red, green, and blue indicated by the PWM signals.

Since laser device drive circuits mostly adopt analog dimming, the PWM signals output by the display control circuit can be converted into analog signals through the digital-to-analog conversion circuit. As shown in FIGS. 3 and 4, Y_ANG, R_ANG, G_ANG, and B_ANG signals respectively represent the analog signals converted from the PWM signals of currents of different colors. The selector switch may combine 4 channels of dimming analog signals output by the digital-to-analog conversion into one channel of laser device drive signal (the LD_ANG_OUT signal shown in FIGS. 3 and 4) and input the one channel of laser device drive signal to the laser device drive circuit. EN_R, EN_G, and EN_B input by the display control circuit to the selector switch respectively indicate the selection of red, green, and blue analog dimming signals. The analog dimming scheme of the laser device drive circuit outputs the corresponding drive current according to the voltage received by the ADJ pin of the laser device drive chip. The laser device drive circuit may adjust the magnitude of the output drive current through a buck structure or a boost topology, thereby realizing brightness adjustment. As shown in FIG. 4, LD_CURRENT may refer to the magnitude of the drive current flowing through the laser device.

The main problems existing in the solution include: a dedicated PWM-to-analog chip (i.e., the digital-to-analog conversion circuit) needs to be deployed in the light source system, which is not conducive to the miniaturization and integration of the board; the PWM-to-analog chip has a delay in responding to changes in the duty cycle of the PWM signal, resulting in a delay in current regulation, which is not conducive to brightness adjustment in high-dynamic or low-dynamic modes.

Considering the aforementioned problems existing in the existing laser projection devices, the present application proposes a light source system that does not require additional deployment of a digital-to-analog conversion circuit but controls the laser device drive circuit through a display control circuit. In the laser projection device provided by the present application, there is no need to deploy a digital-to-analog conversion circuit, which reduces the number of components to be deployed in the light source system, reduces the occupied space of the light source system, improves the miniaturization and integration of the light source system, and reduces the delay in current regulation by eliminating the digital-to-analog conversion circuit.

The technical solution of the present application will be described in detail below with reference to specific embodiments. The following specific embodiments may be combined with each other, and the same or similar concepts or processes may not be repeated in some embodiments.

FIG. 5 is a schematic structural diagram of a light source system according to an embodiment of the present application. As shown in FIG. 5, in some embodiments, the light source system may include a display control circuit 701, a laser drive chip 702, and a laser device module 703. The laser device module 703 includes at least one laser device. A drive signal output end 701a of the display control circuit 701 is connected to a drive signal receiving end 702a of the laser drive chip 702, an enable signal output end 701b of the display control circuit 701 is connected to an enable signal receiving end 702b of the laser drive chip 702, and a drive current output end 702c of the laser drive chip 702 is connected to at least one laser device; the display control circuit 701 is configured to determine at least one channel of laser drive signal, and output the at least one channel of laser drive signal and at least one channel of first enable signal to the laser drive chip 702; the laser drive signal is used to represent the magnitude of a drive current corresponding to a target color displayed by the at least one laser device; the laser drive chip 702 is configured to respond to the at least one channel of first enable signal, adjust the magnitude of the drive current based on the at least one channel of laser drive signal, and output the adjusted drive current to the at least one laser device, so as to turn on the at least one laser device.

The drive signal output end 701a of the display control circuit 701 is used to output a laser drive signal for controlling the dimming of the laser device to the outside, and may also be referred to as a dimming signal output end, the laser drive chip 702 may also be referred to as a laser device drive module; the drive signal receiving end 702a of the laser drive chip 702 may also be referred to as a first end of the laser drive chip 702; the enable signal receiving end 702b of the laser drive chip 702 may also be referred to as a second end of the laser drive chip 702; the drive current output end 702c of the laser drive chip 702 may also be referred to as a third end of the laser drive chip 702.

In the present embodiment, the display control circuit 701 outputs at least one channel of laser drive signal to the laser drive chip 702, so that the laser drive chip 702 can control the laser device to be turned on based on the laser drive signal and the first enable signal. Through the above method, no additional digital-to-analog converter chip needs to be configured in the light source system. This reduces the number of components to be deployed, decreases the occupied space of the light source system, improves the miniaturization and integration of the laser projection device, and reduces the delay in current regulation by eliminating the digital-to-analog conversion circuit.

In some embodiments, the display control circuit 701 may include, for example, a display control unit 7011 and a selector switch unit 7012. Alternatively, the display control circuit 701 may not include the selector switch unit 7012 to further reduce the number of components in the light source system. Taking the case where the display control circuit 701 does not include the selector switch unit 7012 as an example, the display control unit 7011 of the display control circuit 701 may integrate the function of the selector switch, for example, the laser drive chip 702 may include, for example, a constant current integrated circuit (IC), a current regulation circuit, and the like. The laser device may be, for example, a monochromatic laser device. It should be understood that the present application does not limit the color of the monochromatic laser device.

In some embodiments, the display control circuit 701 may be configured to determine a plurality of channels of dimming analog signals based on a video signal to be displayed. The display control circuit 701 may then determine one channel of laser drive signal based on the plurality of channels of dimming analog signals, and output the laser drive signal and a first enable signal to the laser drive chip 702.

The dimming analog signal is used to represent the magnitude of a drive current corresponding to a color displayed by the laser device. By way of example, the dimming analog signals may be the foregoing PWM signals, for example. Taking the dimming analog signal being a PWM signal as an example, different duty cycles of the PWM signal may be used to represent the magnitude of the drive current corresponding to the color displayed by the laser device, for example. The number of channels of the plurality of channels of dimming analog signals may be the same as the number of colors that the laser device can display. For example, the plurality of channels of dimming analog signals may be the foregoing Y_PWM, R_PWM, G_PWM, B_PWM, and the like.

Optionally, after obtaining the plurality of channels of dimming analog signals, the display control circuit 701, for example, may synthesize the plurality of channels of dimming analog signals to obtain the at least one channel of laser drive signal. Optionally, the implementation manner in which the display control circuit 701 synthesizes the plurality of dimming analog signals into at least one channel of laser drive signal may refer to the functions of the digital-to-analog conversion circuit and the selector switch described in the foregoing embodiments, which are not repeated herein. In some embodiments, the display control circuit 701 may integrate a digital-to-analog conversion function and a selector switch function, for example.

the laser drive chip 702 may be configured to respond to the first enable signal, adjust the magnitude of the drive current based on the laser drive signal, and output the adjusted drive current to the laser device, so as to turn on the laser device. In some embodiments, the laser drive chip 702 may, for example, determine a color to be displayed by the laser device based on the first enable signal, then determine the magnitude of the drive current corresponding to the laser device displaying the color according to the laser drive signal corresponding to the color, and adjust the magnitude of the drive current input to the laser device, so that the laser device displays the color with the brightness corresponding to the drive current.

In the present embodiment, the display control circuit 701 synthesizes the plurality of channels of dimming analog signals into one channel of laser drive signal and outputs the laser drive signal to the laser drive chip 702, so that the laser drive chip 702 can control the laser device to turn on based on the one channel of laser drive signal and the first enable signal. Through the above method, no additional digital-to-analog converter chip needs to be configured in the light source system. This reduces the number of components to be deployed, decreases the occupied space of the light source system, improves the miniaturization and integration of the laser projection device, and reduces the delay in current regulation by eliminating the digital-to-analog conversion circuit.

As mentioned above, the display control circuit 701 may include a display control unit 7011 and a selector switch unit 7012; alternatively, the display control circuit 701 may not include the selector switch unit 7012. Taking the case where the display control circuit 701 includes a display control unit 7011 and a selector switch unit as an example, FIG. 6 is a schematic structural diagram of another light source system according to an embodiment of the present application. As shown in FIG. 6, in some embodiments, a first signal output end 7011a of the display control unit 7011 may be connected to a first signal input end 7012a of the selector switch unit 7012. An enable signal output end 7011b of the display control unit 7011 may be connected to an enable signal input end 7012b of the selector switch unit 7012 and an enable signal receiving end 702b of the laser drive chip 702. A selection signal output end 7012c of the selector switch unit 7012 may be connected to a drive signal receiving end 702a of the laser drive chip 702.

In some embodiments, the display control unit 7011 may be, for example, the aforementioned DLP, a System on Chip (SOC), or a Field Programmable Gate Array (FPGA), and the present application does not limit this.

In this implementation, the display control unit 7011 may determine a plurality of channels of dimming signals based on the video signal to be displayed, and output the plurality of channels of dimming signals and a third enable signal to the selector switch unit. The selector switch unit may respond to the third enable signal and synthesize the plurality of channels of dimming signals to obtain a laser drive signal.

In some embodiments, when the laser device module 703 includes one laser device, the display control unit 7011 may, for example, first determine a plurality of channels of dimming PWM signals (digital signals) based on the video signal to be displayed, and then convert the PWM signals into analog signals by means of the digital-to-analog conversion function integrated in the display control unit 7011 to obtain a plurality of channels of dimming analog signals. The third enable signal is used to instruct the selector switch unit 7012 to select the plurality of channels of dimming analog signals for synthesizing the plurality of channels of dimming analog signals, so as to obtain a laser drive signal.

In some embodiments, the display control unit 7011 does not integrate a digital-to-analog conversion function, and the digital-to-analog conversion function is integrated in the laser drive chip 702. The display control unit 7011 may, for example, first determine a plurality of channels of dimming PWM signals based on the video signal to be displayed, and then convert the PWM signals into analog signals by means of the digital-to-analog conversion function integrated in the display control unit, so as to obtain a plurality of channels of dimming analog signals. The third enable signal is used to instruct the selector switch unit 7012 to select the plurality of channels of dimming PWM signals for synthesizing the plurality of channels of dimming PWM signals, so as to obtain a laser drive signal. Subsequently, the laser drive chip 702 performs digital-to-analog conversion on the laser drive signal, and the converted signal is used for regulation of the drive current.

Through the foregoing method, the light source system can obtain the laser drive signal by means of the display control unit 7011 and the selector switch unit 7012, which shows that the laser drive signal can be determined without a digital-to-analog conversion module, and the miniaturization of the light source system is realized.

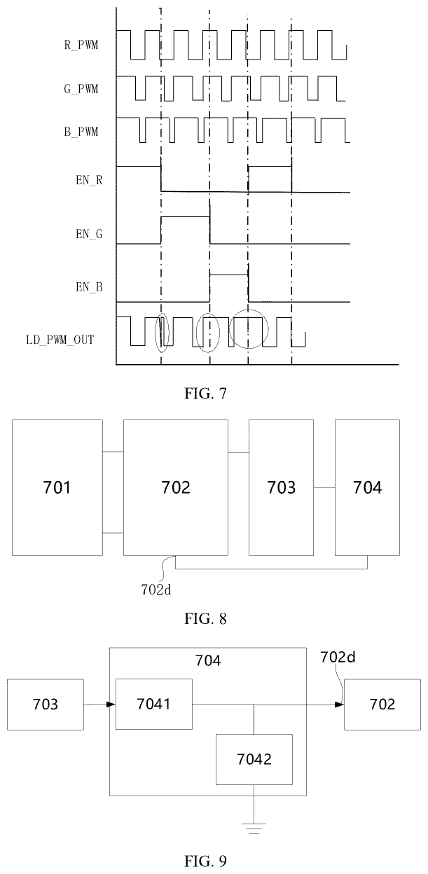

Considering that the light source system may have an abnormal laser drive signal, for example, FIG. 7 is a schematic diagram of an abnormal signal being generated in a laser drive signal in the related art. As shown in FIG. 7, R_PWM, G_PWM, and B_PWM may be respectively used to represent the dimming analog signals corresponding to the laser device displaying red, green, and blue colors; EN_R, EN_G, and EN_B may be respectively used to represent the second enable signals corresponding to the dimming analog signals of red, green, and blue colors. LD_PWM_OUT may be used to represent the laser drive signal. As shown in FIG. 7, the synthesized laser drive signal may have abnormal problems, such as inconsistent and irregular cycle lengths. The main reason for the abnormal problem is that the frequencies of the dimming analog signals of the three colors may be inconsistent with a changing frequency of the second enable signal, leading to abnormal problems during synthesis. For example, as shown in FIG. 7, taking a first circle as an example, at the end of a high level of EN_R, R_PWM is at a low level, and immediately after that, at the start of the high level of EN_G, G_PWM is at a high level; the time difference between the two segments is small, resulting in obvious cycle abnormality of LD_PWM_OUT. Similarly, as shown in the contents of a second circle and a third circle in FIG. 7, the cycles within the circles have the abnormal problem of being too long. However, for the laser drive chip 702, the laser drive chip 702 has a function of adjusting the current cycle by cycle; that is, when the input current has different cycles, the laser drive chip outputs different currents to adjust the brightness of the laser device in this manner. Therefore, the abnormality of the LD_PWM_OUT cycle will lead to abnormal adjustment of the drive current, for example, causing an unintended increase in the brightness of the laser device, which means there may be a problem with poor stability of brightness changes.

Considering the above possible problems, in some embodiments, the laser device projection device may further include a feedback compensation module 704 to filter the abnormal signal in the laser drive signal. For example, FIG. 8 is a schematic structural diagram of yet another light source system according to an embodiment of the present application. As shown in FIG. 8, in some embodiments, the light source system may further include a feedback compensation module 704. As shown in FIG. 8, a first end of the feedback compensation module 704 may be connected to at least one laser device (e.g., a current output end of the laser device, i.e., a cathode of the laser device). A second end of the feedback compensation module 704 may be connected to the laser drive chip 702 (e.g., a feedback signal detection end 702d of the laser drive chip 702). The feedback signal detection end 702d of the laser drive chip 702 may also be referred to as a fourth end of the laser drive chip 702.

The feedback compensation module 704 may be configured to filter the drive current corresponding to the abnormal signal in the laser drive signal to obtain a laser device feedback signal, and output the laser device feedback signal to the laser drive chip 702. the laser drive chip 702 may be configured to adjust the magnitude of the drive current based on the laser device feedback signal and the laser drive signal.

Optionally, the laser device feedback signal may be a voltage signal or a current signal, and the present application does not limit this. Taking the laser device feedback signal being a voltage signal as an example, the feedback compensation module 704 may, for example, convert the drive current corresponding to the laser drive signal into a voltage, and filter the voltage obtained by converting the drive current corresponding to the abnormal signal in the laser drive signal to obtain the laser device feedback signal.

It should be understood that the implementation manner in which the laser drive chip 702 adjusts the magnitude of the drive current based on the laser device feedback signal and the laser drive signal may refer to any existing current regulation manner, for example, and the present application does not limit this. By way of example, taking the laser device feedback signal being a voltage signal as an example, the laser drive chip 702 may, for example, compare the magnitude of the current corresponding to the laser device feedback signal with the magnitude of the drive current input to the laser device. If the current corresponding to the laser device feedback signal is smaller, the laser drive chip 702 may increase the magnitude of the drive current corresponding to the laser drive signal before inputting the drive current to the laser device, so as to improve the accuracy of brightness control for the laser device. If the current corresponding to the laser device feedback signal is larger, the laser drive chip 702 may decrease the magnitude of the drive current corresponding to the laser drive signal before inputting the drive current to the laser device, so as to improve the accuracy of brightness control for the laser device. If the current corresponding to the laser device feedback signal is equal to the drive current input to the laser device, it indicates that the accuracy of the drive current is relatively high, and the laser drive chip 702 may not need to adjust the magnitude of the drive current.

In the present embodiment, the light source system can filter the drive current corresponding to the abnormal signal in the laser drive signal through the feedback compensation module 704, which improves the stability of the laser device feedback signal fed back by the laser device to the laser drive chip 702. Furthermore, this can improve the stability of the drive current that the laser drive chip 702 adjusts for subsequent input to the laser device based on the laser device feedback signal, thereby also improving the safety of the laser device during use and prolonging the service life of the laser device.

The following provides an exemplary description of the structure of the feedback compensation module:

FIG. 9 is a schematic structural diagram of a feedback compensation module according to an embodiment of the present application. As shown in FIG. 9, in some embodiments, the feedback compensation module 704 may include a filtering unit 7041 and an amplifying unit 7042. As shown in FIG. 7, by way of example, a first end of the amplifying unit 7042 may be connected to at least one laser device (e.g., a current output end of the laser device), and a second end of the amplifying unit 7042 may be connected to a first end of the filtering unit 7041 and the laser drive chip 702 (e.g., the feedback signal detection end 702d of the laser drive chip 702). A second end of the filtering unit 7041 may be grounded. The amplifying unit 7042 may be configured to convert the drive current flowing through the at least one laser device into a voltage signal, amplify the voltage signal, and output the amplified voltage signal to the filtering unit 7041.

By way of example, the amplifying unit 7042 may include an amplifier, for example. Optionally, the amplifier may be an error amplifier or an operational amplifier, and the present application does not limit this.

In some embodiments, the amplifying unit 7042 may include a transconductance amplifier. The transconductance amplifier may be a transconductance operational amplifier or a transconductance error amplifier. Taking the case where the amplifying unit 7042 may include a transconductance amplifier as an example, a first end of the transconductance amplifier may be connected to a current output end of at least one laser device (also referred to as a cathode of the at least one laser device). A second end of the transconductance amplifier may be connected to the first end of the filtering unit 7041 and the feedback signal detection end 702d of the laser drive chip 702. Through the above method, the amplifying unit 7042 may convert the drive current flowing through the at least one laser device into a voltage signal and amplify the voltage signal by means of the transconductance amplifier, laying a foundation for subsequent filtering of an abnormal current based on the amplified voltage. Alternatively, optionally, the amplifying unit 7042 may further include other types of components capable of converting a current signal into a voltage signal, as well as amplifiers for amplifying the voltage signal, for example, and the present application does not limit this. The filtering unit 7041 may be configured to filter the corresponding drive current in the abnormal signal based on the amplified voltage signal to obtain a laser device feedback signal.

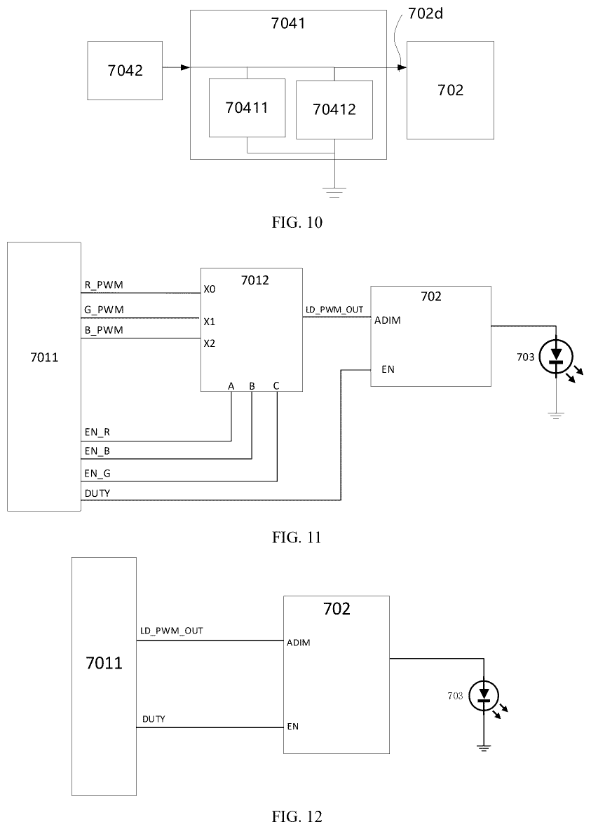

FIG. 10 is a schematic structural diagram of a filtering unit according to an embodiment of the present application. As shown in FIG. 10, in some embodiments, the filtering unit 7041 may include a first filtering subunit 70411 and a second filtering subunit 70412. A first end of the first filtering subunit 70411, a first end of the second filtering subunit 70412, and a second end of the amplifying unit 7042 are all connected to the feedback signal detection end 702d of the laser drive chip 702. A second end of the first filtering subunit 70411 and a second end of the second filtering subunit 70412 may both be grounded.

The first filtering subunit 70411 may be configured to filter the drive current corresponding to the abnormal signal with a frequency less than or equal to a first frequency among abnormal signals. The second filtering subunit 70412 may be configured to filter the drive current corresponding to the abnormal signal with a frequency greater than the first frequency and less than or equal to a second frequency in the abnormal signal. By means of the first filtering subunit 70411 and the second filtering subunit 70412, the light source system can filter out the laser drive signals with frequencies less than or equal to the second frequency as abnormal signals, thereby realizing the filtering of the drive current corresponding to the laser drive signals with excessively low frequencies.

In some embodiments, the frequency of the dimming analog signal may be greater than twice the second frequency. By making the frequency of the dimming analog signal greater than twice the second frequency, the display control circuit ensures that the dimming analog signal without abnormality is not filtered out, and also ensures that the laser device feedback signal corresponding to the normal drive current without abnormality flowing through the laser device can be returned to the laser drive chip 702, thereby realizing a complete control process for turning on the laser device.

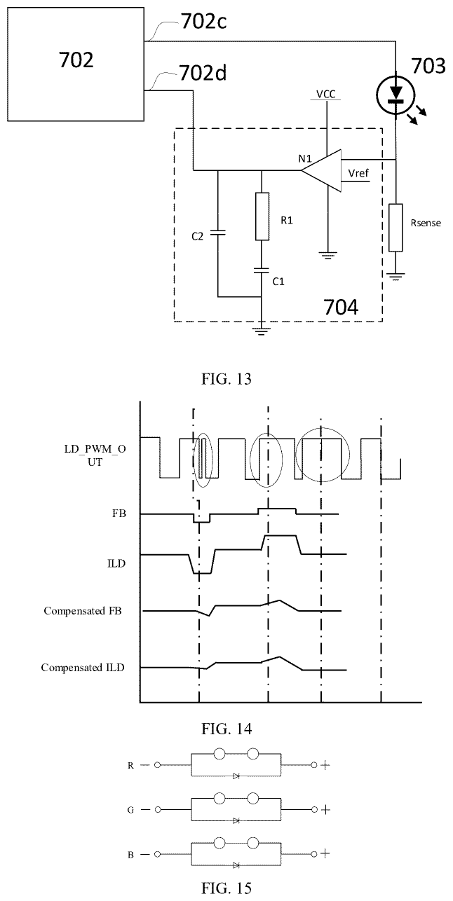

As shown in FIG. 13, in some embodiments, the first filtering subunit 70411 may include a first resistor R1 and a first capacitor C1. A first end of the first resistor R1 may be connected to the feedback signal detection end 702d of the laser drive chip 702 (that is, also connected to the second end of the amplifying unit 7042). A second end of the first resistor R1 may be grounded via the first capacitor C1. Optionally, the first filtering subunit 70411 may realize the filtering of the drive current corresponding to the abnormal signal with a frequency less than or equal to the first frequency through the charging and discharging process of the first resistor R1 and the first capacitor C1, for example.

In some embodiments, the second filtering subunit 70412 may include a second capacitor C2, for example. A first end of the second capacitor C2 may be connected to the feedback signal detection end 702d of the laser drive chip 702 (that is, also connected to the second end of the amplifying unit 7042). A second end of the second capacitor C2 may be grounded. Optionally, the first filtering subunit 70411 may, for example, realize the filtering of the drive current corresponding to the abnormal signal with a frequency less than the second frequency through the charging and discharging process of the second capacitor C2.

In some embodiments, the first frequency and the second frequency may, for example, be related to a resistance value of the first resistor R1, a transconductance coefficient of the transconductance amplifier, and a capacitance value of the first capacitor C1. Alternatively, the first frequency and the second frequency may, for example, also be related to a resistance value of the first resistor R1, a transconductance coefficient of the transconductance amplifier, a capacitance value of the first capacitor C1, and a capacitance value of the second capacitor C2, and the present application does not limit this.

By way of example, taking the display control circuit 701 including a display control unit 7011 and a selector switch unit 7012 as an example, FIG. 11 is a schematic structural diagram of yet another light source system according to an embodiment of the present application. The display control unit 7011 may be a display control circuit. The selector switch unit 7012 may be a selector switch as shown in FIG. 11. the laser drive chip 702 may be the aforementioned laser device drive circuit. The display control unit 7011 outputs the first enable signal to the laser drive chip 702 via a DUTY pin. ADIM represents a receiving pin for the laser drive signal, i.e., the drive signal receiving end 702a.

By integrating a PWM-to-analog conversion function inside a chip of the display control unit 7011, the display control unit 7011 can generate PWM control signals of colors such as red, green, blue, and yellow based on a frame synchronization signal. Through a PWM-to-analog chip function, the display control unit converts the PWM signals into dimming analog signals and outputs the dimming analog signals to the selector switch. The selector switch can synthesize 4 channels of dimming analog signals output by the display control circuit into one channel of laser drive signal, and input the laser drive signal to the laser drive chip 702.

The above solution adopts the integration of the PWM-to-analog chip function inside the chip instead of directly inputting PWM signals to the selector switch. This is because a continuous current is output in an analog drive mode, while in the PWM solution, the laser device is in an on-off state, which easily causes the piezoelectric effect of a ceramic capacitor in the circuit, generates an alternating magnetic field on the inductor, or causes vibration of the laser device itself, leading to abnormal noise. Therefore, the light source system as shown in FIG. 11 can also reduce noise through analog signals. In addition, in PWM dimming, when the laser device is powered on, the switch and inductor are always conducting a maximum current, resulting in increased conduction losses of the power switch and the inductor. In contrast, the power loss of analog signals is low, so the generation of heat flow can be reduced, which in turn reduces reliance on heat dissipation materials and further reduces the space occupied by the device.

Through integrating a PWM-to-analog conversion circuit into a drive IC inside the display control unit 7011, not only is the integration and miniaturization of the drive circuit facilitated, but, because a PWM sampling clock inside the chip is higher than a PWM input frequency, any change in the duty cycle can be responded to within a single PWM period. Therefore, the efficiency of responding to changes in the duty cycle is further improved, and the accuracy of brightness control of the light source system is improved accordingly. Furthermore, with the light source system as shown in FIG. 11, an analog output reference voltage and a reference voltage of the drive IC (i.e., the display control unit) are integrated in the same IC, enabling the sharing of the same reference source. Compared with the related art, where inconsistent reference voltages easily cause noise, the present application also improves the accuracy of output current regulation.

FIG. 12 is a schematic structural diagram of yet another light source system according to an embodiment of the present application. As shown in FIG. 12, the light source system may also not include the selector switch. The meanings of various parameters in the light source system may be explained with reference to parameters provided in the foregoing embodiments, and details will not be repeated here.

As mentioned above, when the light source system shown in FIG. 11 and FIG. 12 changes colors, the inconsistency between the frequency of the dimming analog signal and the changing frequency of the enable signal may lead to inconsistent and irregular cycle lengths of the synthesized laser drive signal. As shown in FIG. 13, the light source system may further include a feedback compensation module 704. A resistor Rsense may be a sampling resistor of the laser device. A resistor R1 in the feedback compensation module 704 may be the first resistor, the capacitor C1 may be the first capacitor, and the capacitor C2 may be the second capacitor. The transconductance amplifier N1 may be the amplifying unit 7042. Vref represents a reference voltage input end of the amplifier, and VCC represents an operating voltage pin of the amplifier. Other components in this circuit diagram may refer to the content described in the above embodiments, and details will not be repeated here.

The following provides an exemplary description of how to select the transconductance amplifier and how to determine the values of the first capacitor C1, the second capacitor C2, and the first resistor R1:

Taking the feedback compensation module 704 (also referred to as a feedback compensation circuit) in the light source system shown in FIG. 13 as an example, a transfer function of the feedback compensation circuit may be expressed, for example, by the following Formula (1):

$$G ( s ) = A g \frac{1 + s / ω ze}{1 + s / ω hf} \qquad ( 1 )$$

$$where ω ze = \frac{1}{R c o m p * C c o m p} ; ω ze \approx \frac{1}{R c o m p * C h f} ;$$

Ag=Rcomp*gm, where gm is a transconductance coefficient of the transconductance amplifier; Rcomp represents the resistance value of the first resistor R1, Ccomp represents the capacitance value of the first capacitor C1, and Chf represents the capacitance value of the second capacitor C2. s may be a complex frequency domain variable used to represent an input signal of the feedback compensation circuit.

By selecting a transconductance error amplifier with an appropriate transconductance coefficient and adjusting the resistance value of the first resistor R1 and the capacitance value of the first capacitor C1, the loop bandwidth of the feedback compensation circuit can be adjusted to meet the requirement for a rising edge time of the laser drive signal output by the laser device drive circuit (to ensure that an image is not affected and the image quality is not affected under a low grayscale). By way of example, the loop bandwidth of the feedback compensation circuit may be expressed by the following Formula (2):

$$B W = \frac{0.35}{tres} \qquad ( 2 )$$

where tres represents a maximum value of the rising edge time (10%-90%) of the laser drive signal, and BW represents the loop bandwidth. For example, assuming the light source system is a laser TV capable of displaying 4K 60 Hz images: since 4K images are generated by modulating 4 frames of 1080P images via a galvanometer, and the frame rate of 1080P is 240 Hz, tres can be set to 20 uS according to the picture quality requirements for high dynamic range or low dynamic range images. In this case, the loop bandwidth is

$$BW = \frac{0.35}{tres} = \frac{0.35}{20 uS} = 17.5 KHz .$$

If the frequency of the PWM dimming analog signal sent by an SOC or DLP system is set to twice the bandwidth or higher, the frequency of the PWM dimming analog signal can be set to 35 KHz or above.

With the feedback compensation module 704 as shown in FIG. 13, FIG. 14 is a timing diagram of a laser device feedback signal and a drive current according to an embodiment of the present application. As shown in FIG. 14, LD_PWM_OUT may be used to represent the laser drive signal, and the content within the circle is the abnormal signal in the laser drive signal. As shown in FIG. 14, if the feedback compensation module 704 is not deployed in the light source system, when corresponding to the abnormal signal, the stability of both the laser device feedback signal FB and the laser device drive current ILD is poor. If the feedback compensation module 704 is deployed in the light source system, the stability of the feedback signal FB (i.e., the compensated FB) and the laser device drive current ILD (i.e., the compensated ILD) is improved.

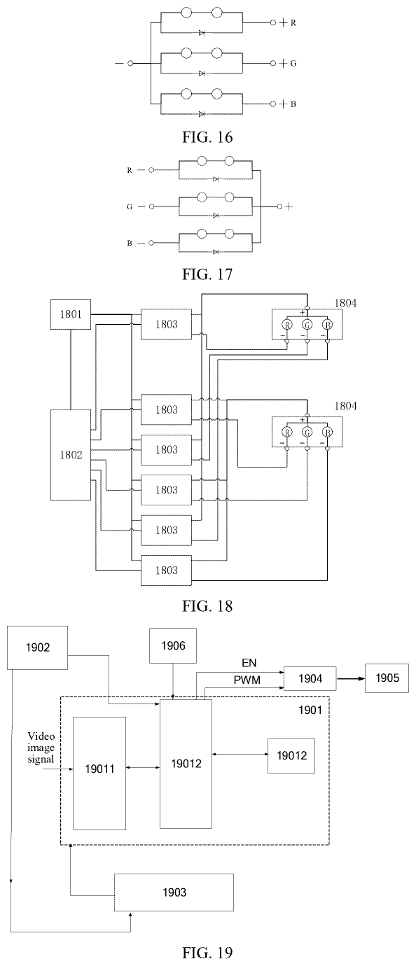

To reduce the space occupied by the light source system, the size of the light source system is becoming increasingly smaller, and the laser devices therein are also being miniaturized accordingly. One direction for miniaturization is to replace an ordinary laser device with a common-cathode laser device or a common-anode laser device. FIG. 15 is a schematic diagram of a circuit structure of parallel-connected laser devices in the related art. As shown in FIG. 15, pins of sub-laser devices (or laser light sources) in the laser device are independent of each other. FIG. 16 is a schematic diagram of a common-cathode laser device circuit in the related art, and FIG. 17 is a schematic diagram of a common-anode laser device circuit in the related art. As shown in FIG. 16, the laser devices in the common-cathode laser device share a single cathode pin; as shown in FIG. 17, the laser devices in the common-anode laser device share a single anode pin. Therefore, common-cathode laser devices or common-anode laser devices can save pin space and achieve miniaturization of the laser device.

In the related art, to improve the projection brightness of the light source system, a plurality of laser devices are usually used. For the connection mode of the plurality of laser devices, series connection is difficult due to the shared pins in common-cathode laser devices or common-anode laser devices, so parallel connection is generally adopted. In addition, each sub-laser device corresponding to each emission color in each common-cathode or common-anode laser device needs to be equipped with a separate control chip.

FIG. 18 is a schematic diagram of a circuit structure of parallel-connected common-anode laser devices provided in the related art. As shown in FIG. 18, the structure of the parallel-connected common-anode laser devices includes a power supply 1801, a display control assembly 1802, six constant current assemblies 1803, and two common-anode laser devices 1804. The power supply 1801 supplies power to the display control assembly 1802 and the constant current assemblies 1803. The display control assembly 1802 controls the constant current assemblies 1803 to output current to the common-anode laser devices 1804, so that the common-anode laser devices 1804 are turned on. Red sub-laser devices R, green sub-laser devices G, and blue sub-laser devices B in the two common-anode laser devices 1804 receive current output from separate constant current assemblies 1803, respectively. Therefore, when laser devices of the same emission color are turned on simultaneously, there will be differences in the current flowing through the laser devices, which will lead to differences in the brightness of the displayed image. In addition, since each sub-laser device is equipped with one constant current assembly 1803, problems such as a large number of constant current assemblies 1803, high cost, inconvenience for miniaturization, and strong common magnetic interference are caused.

In some embodiments, as shown in FIGS. 1 and 2, in the laser projection device, may include a plurality of common-cathode bicolor laser devices or a plurality of common-anode bicolor laser devices (e.g., blue laser devices and red laser devices). Alternatively, the light source system 100 may include a plurality of common-cathode tricolor laser devices or a plurality of common-anode tricolor laser devices. The tricolor laser devices include laser devices of red, green and blue emission colors and are used to provide a tricolor laser illumination beam.

FIG. 19 is a schematic diagram of a circuit structure of a light source system according to an embodiment of the present application. As shown in FIG. 19, the light source system includes a display board 1901, a power board 1902, and a TV board 1903. The power board 1902 is connected to the display board 1901 and the TV board 1903 respectively, and can be used to supply power to various devices or part of modules on the display board 1901 and the TV board 1903. The TV board 1903 is mainly used to receive external audio and video signals, decode the signals, and output video image signals to the display board 1901. The display board 1901 may be provided with a Field Programmable Gate Array (FPGA) and an algorithm processing module 19011, which are used to process the input video image signals. A display control assembly 19012 is connected to the algorithm processing module 19011 and is configured to receive processed video image signal data, which serves as image data to be displayed. The display board 1901 is used to generate initial drive signals for driving laser devices and image display drive signals for driving light modulation devices.

The display control assembly 19012 is used to generate, based on the image signals to be displayed, on one hand, an image display drive signal for driving a light modulation device 19013; on the other hand, since the display of projected images requires the synchronous cooperation of light source beams and the light modulation device, the display control assembly 19012 also generates drive signals for driving the light source to emit light. The drive signals may include an initial image enable signal EN and an initial current control signal, e.g., a Pulse Width Modulation (PWM) signal. Among them, the initial image enable signal EN is a timing control signal used to coordinate the timing of light output of different emission colors, while the PWM signal is a periodic square wave signal used to control the brightness of the laser devices.

A laser device drive circuit 1904 is configured to receive the image enable signal EN and the PWM signal output by the display control assembly 19012, and directly control the laser devices 1905 to be turned on. A signal shaping circuit 1906 may be used to generate periodic sub-signals, shape the image enable signal EN or the PWM signal, and affect the signal waveform and period finally output to the laser devices 1905.

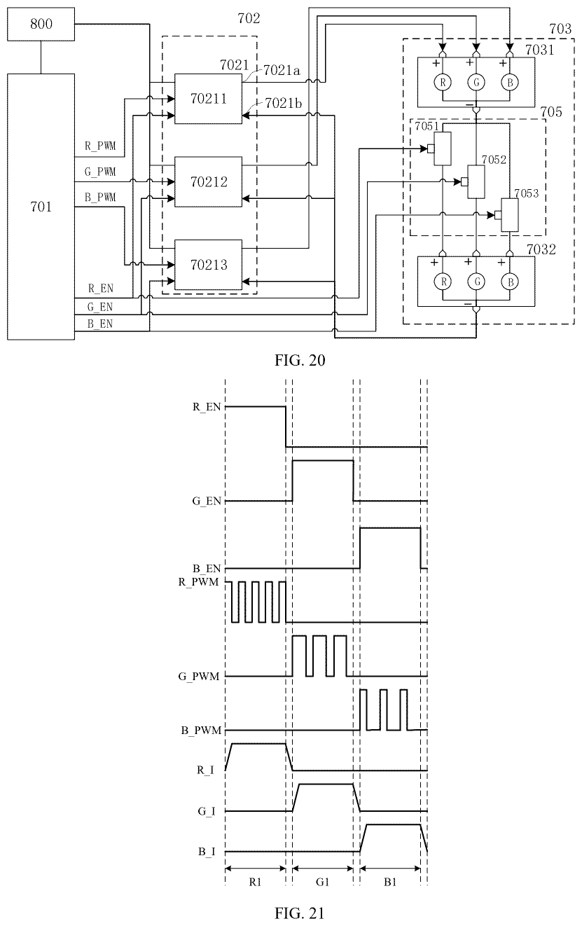

FIG. 20 is a schematic structural diagram of yet another light source system according to an embodiment of the present application. As shown in FIG. 20, in some embodiments, the laser device module 703 includes at least two laser devices, and the at least two laser devices are arranged in series; the light source system further includes at least one first switch assembly 705, and the at least two laser devices are connected via the first switch assembly 705. By arranging at least two laser devices in series, the laser device module 703 can not only provide higher projection brightness for the light source system, but also ensure that the current flowing through different laser devices is the same, thereby achieving consistent brightness, which is beneficial to the quality of the projected images. In addition, the at least two laser devices are connected via the first switch assembly 705. The first switch assembly 705 can be used to switch light sources of different colors, and also to short-circuit different laser devices in a series loop so that the laser devices no longer receive the laser drive signal and the enable signal. This can be applied to the short-circuiting of faulty laser devices to ensure the normal operation of intact laser devices, and can also be used to make a single laser device emit light independently, improving the control flexibility of the laser device module 703.

In some embodiments, the at least two laser devices are all common-cathode laser devices or common-anode laser devices. With reference to FIG. 25, when the laser devices are common-cathode laser devices 70301, four common-cathode laser devices 70301 are sequentially connected in series, and a common cathode of the previous common-cathode laser device 70301 is connected to a plurality of anodes of the next common-cathode laser device 70301, respectively. The first switch assembly 705 may be arranged between two common-cathode laser devices 70301. One end of the first switch assembly 705 is connected to the common cathode of the previous common-cathode laser device 70301, and the other end thereof is connected to the anode of the next common-cathode laser device 70301. There may be one first switch assembly 705, which is used to control the connection or disconnection between the common cathode and the plurality of anodes, or to control the connection or disconnection between the common cathode and one of the anodes; there may be a plurality of first switch assemblies 705, which are used to respectively control the connection or disconnection between the common cathode and the plurality of anodes, or to respectively control the connection or disconnection between the common cathode and each anode.

With reference to FIG. 26, when the laser devices are common-anode laser devices 70302, four common-anode laser devices 70302 are sequentially connected in series, and a cathode of the previous common-anode laser device 70302 is connected to a common anode of the next common-anode laser device 70302, respectively. The first switch assembly 705 may be arranged between two common-anode laser devices 70302. One end of the first switch assembly 705 is connected to the cathode of the previous common-anode laser device 70302, and the other end thereof is connected to the common anode of the next common-anode laser device 70302. There may be one first switch assembly 705, which is used to control the connection or disconnection between a plurality of cathodes and the common anode, or to control the connection or disconnection between one of the cathodes and the common anode; there may be a plurality of first switch assemblies 705, which are used to respectively control the connection or disconnection between the plurality of cathodes and the common anode, or to respectively control the connection or disconnection between each anode and the common anode.

As shown in FIG. 20, in some embodiments, the light source system may include a display control circuit 701, a laser drive chip 702, and a laser device module 703. The laser device module 703 further includes a plurality of (alternatively described as at least two) laser devices and a plurality of (alternatively described as at least two) first switch assemblies 705 (only two laser devices and three switch assemblies are shown in FIG. 20, which are common-cathode tricolor laser devices 7031 and 7032, and first switch assemblies 7051, 7052 and 7053, respectively). The plurality of laser devices are common-cathode laser devices or common-anode laser devices, and are connected via the plurality of first switch assemblies 705.

the laser drive chip 702 includes a plurality of constant current assemblies 7021 (three constant current assemblies 7021 are shown in FIG. 20, which are constant current assemblies 70211, 70212, and 70213, respectively); the plurality of constant current assemblies 7021 are connected to the laser device module 703. By way of example, in FIG. 20, a current output end of the constant current assembly 70211 is connected to an anode of a red sub-laser device of the common-cathode tricolor laser device 7031 in the laser device module 703; a current output end of the constant current assembly 70212 is connected to an anode of a green sub-laser device of the common-cathode tricolor laser device 7031 in the laser device module 703; a current output end of the constant current assembly 70213 is connected to an anode of a blue sub-laser device of the common-cathode tricolor laser device 7031 in the laser device module 703; and current return ends of the constant current assemblies 70211, 70212 and 70213 are connected to a common cathode of the common-cathode tricolor laser device 7032.

The display control circuit 701 is connected to the plurality of constant current assemblies 7021 and the plurality of first switch assemblies 705, respectively, and is configured to output laser drive signals (e.g., PWM signals or analog signals) and first enable signals to the constant current assemblies 7021, and output second enable signals to the first switch assemblies 705.

As shown in FIG. 20, in some embodiments, each laser device includes at least two laser light sources corresponding to different colors. Laser light sources of the same color among all the laser devices are sequentially connected in series to one constant current assembly 7021, and a first switch assembly 705 is disposed between two adjacent laser light sources. A single first switch assembly 705 can control the connection or disconnection between two laser light sources of the same color in two adjacent laser devices. When the two laser light sources are powered on, current can flow through both the laser light sources, and both the two laser light sources emit light simultaneously; when the two laser light sources are turned off, no current can flow through the two laser light sources, and neither can emit light. The plurality of laser light sources in each laser device serve as light source elements to emit light of different colors, thereby enabling the laser device to form a multi-color laser device. A laser light source may also be referred to as a sub-laser device.

By way of example, in FIG. 20, each laser device includes three laser light sources (or referred to as sub-laser devices), where a laser light source R (or referred to as a red sub-laser device) is used to emit red light, a laser light source G (or referred to as a green sub-laser device) is used to emit green light, and a laser light source B (or referred to as a blue sub-laser device) is used to emit blue light. The display control circuit 701 is connected to the constant current assemblies 70211, 70212, and 70213, as well as to the first switch assemblies 7051, 7052, and 7053; the display control circuit 701 outputs a red PWM signal R_PWM to the constant current assembly 70211, a green PWM signal G_PWM to the constant current assembly 70212, and a blue PWM signal B_PWM to the constant current assembly 70213, and outputs an enable signal R_EN corresponding to red to the constant current assembly 70211 and the first switch assembly 7051, an enable signal G_EN corresponding to green to the constant current assembly 70212 and the first switch assembly 7052, and an enable signal B_EN corresponding to blue to the constant current assembly 70213 and the first switch assembly 7053.

The first switch assembly 705 is configured to turn on the plurality of laser devices when the received second enable signal is at an effective potential; the effective potential refers to a high potential, also known as a high level. The constant current assembly 7021 is configured to drive the laser device module 703 to emit light based on the PWM signal when the received enable signal is at an effective potential.

By way of example, FIG. 21 is a timing diagram of the enable signal, the PWM signal, and the current according to an embodiment of the present application. Both the enable signal and the PWM signal are periodic signals, and FIG. 21 shows the enable signal and the PWM signal within one period. As shown in FIG. 21, within a time period R1 in one period (which is also a laser operating period of the red sub-laser device), the enable signal R_EN is at a high level, the enable signals G_EN and B_EN are at a low level, the red PWM signal R_PWM is a square wave signal, and the green PWM signal G_PWM and the blue PWM signal B_PWM are at a low level. During the time period R1, the current R_I flowing through the red sub-laser device first increases from 0 and then remains constant; during the period from the end of the time period R1 to the start of the time period G1, the current R_I gradually decreases to 0.

Within the time period G1 in one cycle, which is also the laser operating period of the green sub-laser device, the enable signal R_EN is at a low level, the enable signal G_EN is at a high level, and the enable signal B_EN is at a low level; the red PWM signal R_PWM is a low-level signal, the green PWM signal G_PWM is a square wave signal, and the blue PWM signal B_PWM is a low-level signal. During the time period G1, the current G_I flowing through the green sub-laser device first increases from 0 and then remains constant; during the period from the end of the time period G1 to the start of the time period B1, the current G_I gradually decreases to 0.

Within the time period B1 in one cycle, which is also the laser operating period of the blue sub-laser device, the enable signal R_EN is at a low level, the enable signal G_EN is at a low level, and the enable signal B_EN is at a high level; the red PWM signal R_PWM is a low-level signal, the green PWM signal G_PWM is a low-level signal, and the blue PWM signal B_PWM is a square wave signal. During the time period B1, the current B_I flowing through the blue sub-laser device first increases from 0 and then remains constant; during the period from the end of the time period B1 to the start of the next time period R1, the current B_I gradually decreases to 0. The duty cycles of the red PWM signal R_PWM, the green PWM signal G_PWM, and the blue PWM signal B_PWM may be the same or different.

For example, in FIG. 20, when the enable signal R_EN received by the first switch assembly 7051 is at a high level, the first switch assembly 7051 switches to an on state, thereby enabling electrical conduction between the common cathode of the common-cathode tricolor laser device 7031 and the anode of the red sub-laser device of the common-cathode tricolor laser device 7032. When the enable signal R_EN received by the constant current assembly 70211 is at a high level, the constant current assembly 70211 applies a drive voltage to the laser device module 703 based on the received signal R_PWM, and outputs a current through the current output end. The current sequentially flows through the red sub-laser device of the common-cathode tricolor laser device 7031, the switch assembly 7051, and the red sub-laser device of the common-cathode tricolor laser device 7032, then flows back to the constant current assembly 70211 through the current return end of the constant current assembly 70211. The red sub-laser device of the common-cathode tricolor laser device 7031 and the red sub-laser device of the common-cathode tricolor laser device 7032 are turned on and emit red light.

When the enable signal G_EN received by the first switch assembly 7052 is at a high level, the first switch assembly switches to an on state, thereby enabling electrical conduction between the common cathode of the common-cathode tricolor laser device 7031 and the anode of the green sub-laser device of the common-cathode tricolor laser device 7032. At this time, the enable signal G_EN received by the constant current assembly 70212 is at a high level.

Based on the received signal G_PWM, the constant current assembly 70212 applies a drive voltage to the laser device module 703 and outputs a current through the current output end. The current sequentially flows through the green sub-laser device of the common-cathode tricolor laser device 7031, the first switch assembly 7051 and the green sub-laser device of the common-cathode tricolor laser device 7032, then flows back to the constant current assembly 70212 through the current return end of the constant current assembly 70212. At this point, the green sub-laser device of the common-cathode tricolor laser device 7031 and the green sub-laser device of the common-cathode tricolor laser device 7032 are turned on and emit green light.

When the enable signal B_EN received by the first switch assembly 7053 is at a high level, the first switch assembly 7053 switches to an on state, enabling electrical conduction between the common cathode of the common-cathode tricolor laser device 7031 and the anode of the blue sub-laser device of the common-cathode tricolor laser device 7032. At this time, the enable signal B_EN received by the constant current assembly 70213 is at a high level. Based on the received B_PWM signal, the constant current assembly 70213 applies a drive voltage to the laser device module 703 and outputs a current through the current output end. The current sequentially flows through the blue sub-laser device of the common-cathode tricolor laser device 7031, the first switch assembly 7051, and the blue sub-laser device of the common-cathode tricolor laser device 7032, then flows back to the constant current assembly 70213 through the current return end of the constant current assembly 70213. At this point, the blue sub-laser device of the common-cathode tricolor laser device 7031 and the blue sub-laser device of the common-cathode tricolor laser device 7032 are turned on and emit blue light.

It should be noted that the light source system further includes a power supply 800. The power supply 800 is connected to the display control circuit 701 and each constant current assembly 7021, and is used to supply power to the display control circuit 701 and each constant current assembly 7021. As shown in FIG. 20, the light source system further includes the power supply 800, which is connected to the display control circuit 701, the constant current assembly 70211, the constant current assembly 70212, and the constant current assembly 70213, respectively. The following is an explanation of the series connection of laser devices. If the laser devices in the light source system are common-cathode laser devices, for the first laser device and the second laser device among the two series-connected laser devices, the anodes of the sub-laser devices in the second laser device are respectively connected to the first ends of the corresponding first switch assemblies; the second ends of the switch assemblies connected to the second laser device are connected to the common cathode of the first laser device.

In some embodiments, as shown in FIG. 20, the laser devices shown in FIG. 20 are common-cathode tricolor laser devices, where the first laser device is the common-cathode tricolor laser device 7031 and the second laser device is the common-cathode tricolor laser device 7032. The anode of the red sub-laser device in the common-cathode tricolor laser device 7032 is connected to the first end of the first switch assembly 7051 corresponding to red; the anode of the green sub-laser device in the common-cathode tricolor laser device 7032 is connected to the first end of the first switch assembly 7052 corresponding to green; the anode of the blue sub-laser device in the common-cathode tricolor laser device 7032 is connected to the first end of the first switch assembly 7053 corresponding to blue. The common cathode of the common-cathode tricolor laser device 7031 is connected to the second ends of the first switch assembly 7051, 7052 and 7053, respectively.

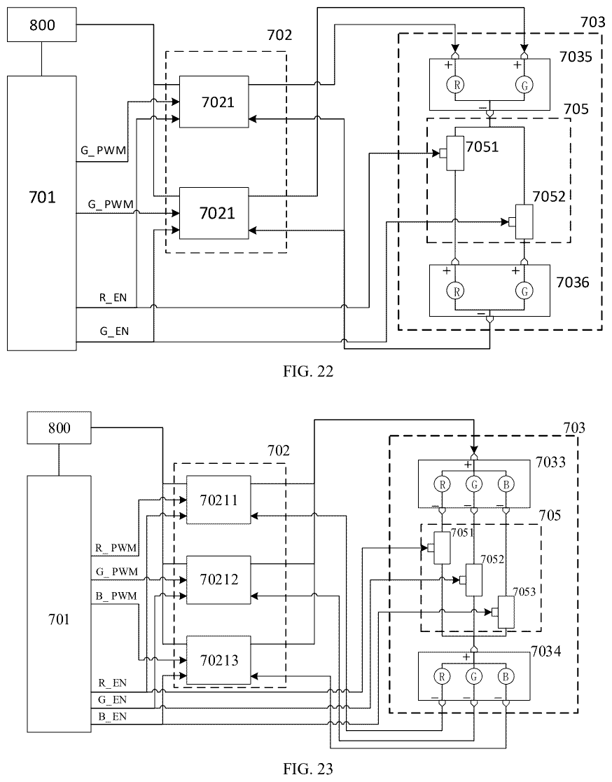

It should be noted that the laser devices in the light source system may also be common-cathode bicolor laser devices. FIG. 22 is a schematic structural diagram of yet another light source system according to an embodiment of the present application. As shown in FIG. 22, by way of example, the laser devices in the figure are common-cathode bicolor laser devices, where the sub-laser devices are red sub-laser devices and green sub-laser devices, the laser drive chip 702 also includes only two constant current assemblies 7021, which are the constant current assembly 70211 and the constant current assembly 70212, respectively. The current output end of the constant current assembly 70211 is connected to an anode of a red sub-laser device of the common-cathode bicolor laser device 713 in the laser device module 703; the current output end of the constant current assembly 70212 is connected to an anode of the green sub-laser device of the common-cathode bicolor laser device 713 in the laser device module 703; the current return ends of the constant current assembly 70211 and the constant current assembly 70212 are connected to a common cathode of the common-cathode bicolor laser device 714.

In FIG. 22, the first laser device is the common-cathode bicolor laser device 7035, and the second laser device is the common-cathode bicolor laser device 7036. The anode of the red sub-laser device in the common-cathode bicolor laser device 7036 is connected to the first end of the first switch assembly 7051 corresponding to red; the anode of the green sub-laser device in the common-cathode bicolor laser device 7036 is connected to the first end of the first switch assembly 7052 corresponding to green; the common cathode of the common-cathode bicolor laser device 7035 is respectively connected to the second ends of the first switch assembly 7051 and the first switch assembly 7052.

It should be noted that the sub-laser devices in the common-cathode bicolor laser device may also be blue sub-laser devices and green sub-laser devices, or red sub-laser devices and blue sub-laser devices. The embodiments of the present application do not limit the sub-laser devices in the bicolor laser device, which can be set according to actual conditions.

If the laser devices in the light source system are common-anode laser devices, for the third laser device and the fourth laser device among the two series-connected laser devices, the cathodes of the sub-laser devices in the third laser device are respectively connected to the first ends of the corresponding switch assemblies; the second ends of the switch assemblies connected to the third laser device are connected to the common anode of the fourth laser device.

FIG. 23 is a schematic structural diagram of yet another light source system according to an embodiment of the present application. As shown in FIG. 23, in some embodiments, the laser devices in the figure are common-anode laser devices, which are common-anode tricolor laser devices 7033 and 7034, respectively. The current output ends of the constant current assemblies 70211, 70212, and 70213 are connected to the common anode of the common-anode tricolor laser device 7033 in the laser device module 703; the current return end of the constant current assembly 70211 is connected to the cathode of the red sub-laser device of the common-anode tricolor laser device 7034; the current return end of the constant current assembly 70212 is connected to the cathode of the green sub-laser device of the common-anode tricolor laser device 7034; the current return end of the constant current assembly 70213 is connected to the cathode of the blue sub-laser device of the common-anode tricolor laser device 7034.

In FIG. 23, the third laser device is the common-anode tricolor laser device 7033, and the fourth laser device is the common-anode tricolor laser device 7034. The cathode of the red sub-laser device in the common-anode tricolor laser device 7033 is connected to the first end of the first switch assembly 7051 corresponding to red; the cathode of the green sub-laser device in the common-anode tricolor laser device 7033 is connected to the first end of the first switch assembly 7052 corresponding to green; the cathode of the blue sub-laser device in the common-anode tricolor laser device 7033 is connected to the first end of the first switch assembly 7053 corresponding to blue. The common anode of the common-anode tricolor laser device 7034 is respectively connected to the second ends of the first switch assembly 7051, the first switch assembly 7052, and the first switch assembly 7053.

When the enable signal R_EN received by the first switch assembly 7051 is at a high level, the first switch assembly 7051 switches to the on state, enabling electrical conduction between the cathode of the red sub-laser device of the common-anode tricolor laser device 7033 and the common anode of the common-anode tricolor laser device 7034. When the enable signal G_EN received by the first switch assembly 7052 is at a high level, the first switch assembly 7052 switches to the on state, enabling electrical conduction between the cathode of the green sub-laser device of the common-anode tricolor laser device 7033 and the common anode of the common-anode tricolor laser device 7034. When the enable signal B_EN received by the first switch assembly 7053 is at a high level, the first switch assembly 7053 switches to the on state, enabling electrical conduction between the cathode of the blue sub-laser device of the common-anode tricolor laser device 7033 and the common anode of the common-anode tricolor laser device 7034.

When the enable signal R_EN received by the constant current assembly 70211 is at a high level, the constant current assembly 70211 applies a drive voltage to the laser device module 703 based on the received signal R_PWM, and outputs a current through the current output end. The current sequentially flows through the red sub-laser device of the common-anode tricolor laser device 7033, the first switch assembly 7051, and the red sub-laser device of the common-anode tricolor laser device 7034, then flows back to the constant current assembly 70211 through the current return end of the constant current assembly 70211. At this point, the common cathode of the common-anode tricolor laser device 7033 and the red sub-laser device of the common-anode tricolor laser device 7034 are turned on and emit red light. When the enable signal R_EN received by the constant current assembly 70211 is at a high level, the enable signals received by the constant current assemblies 70212 and 70213 are at a low level, the constant current assemblies 70212 and 70213 will not receive a current from the common-anode tricolor laser device 7034. Therefore, the common cathode of the common-anode tricolor laser device 7033 and the green sub-laser device and blue sub-laser device in the common-anode tricolor laser device 7034 will not be turned on. It should be noted that the process of turning on the green sub-laser device and the blue sub-laser device is similar to the process of turning on the red sub-laser device, and will not be repeated here.

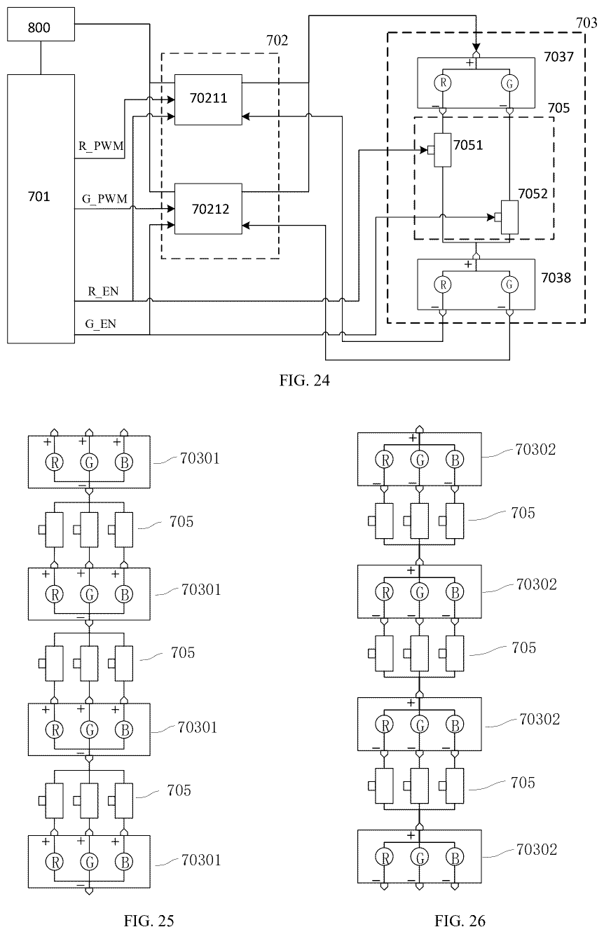

It should be noted that the laser devices in the light source system may also be common-anode bicolor laser devices. FIG. 24 is a schematic structural diagram of yet another light source system according to an embodiment of the present application. As shown in FIG. 24, by way of example, the laser devices in the figure are common-anode bicolor laser devices, where the sub-laser devices are red sub-laser devices and green sub-laser devices, the laser drive chip 702 also includes only two constant current assemblies 7021, which are the constant current assembly 70211 and the constant current assembly 70212, respectively. The current output ends of the constant current assembly 70211 and the constant current assembly 70212 are connected to the common anode of the common-anode bicolor laser device 7037 in the laser device module 703; the current return end of the constant current assembly 70211 is connected to the cathode of the red sub-laser device of the common-anode bicolor laser device 7038, and the current return end of the constant current assembly 70212 is connected to the cathode of the green sub-laser device of the common-anode bicolor laser device 7038.

In FIG. 24, the third laser device is the common-anode bicolor laser device 7037, and the fourth laser device is the common-anode bicolor laser device 7038. The cathode of the red sub-laser device in the common-anode bicolor laser device 7037 is connected to the first end of the first switch assembly 7051 corresponding to red; the cathode of the green sub-laser device in the common-anode bicolor laser device 7037 is connected to the first end of the first switch assembly 7052 corresponding to green; the common anode of the common-anode bicolor laser device 7038 is connected to the second ends of the first switch assembly 7051 and the first switch assembly 7052, respectively.

It should be noted that the sub-laser devices in the common-anode bicolor laser device may also be blue sub-laser devices and green sub-laser devices, or red sub-laser devices and blue sub-laser devices. The embodiments of the present application do not limit the sub-laser devices in the bicolor laser device, which can be set according to actual conditions.

FIG. 25 is a schematic diagram of a circuit structure of multiple series-connected common-cathode tricolor laser devices according to an embodiment of the present application. As shown in FIG. 25, by way of example, four common-cathode tricolor laser devices 70301 are shown. For every two series-connected common-cathode tricolor laser devices 70301: the anode of the red sub-laser device of one common-cathode tricolor laser device is connected to one end of the first switch assembly 705 corresponding to red; the anode of the green sub-laser device is connected to one end of the first switch assembly 705 corresponding to green; the anode of the blue sub-laser device is connected to one end of the first switch assembly 705 corresponding to blue; and the common cathode of the other common-cathode tricolor laser device 70301 is connected to the other ends of the three first switch assemblies 705. For the first common-cathode tricolor laser device 70301 among the four series-connected common-cathode tricolor laser devices 70301: the anode of the red sub-laser device is connected to the current output end of the constant current assembly 7021 corresponding to red; the anode of its green sub-laser device is connected to the current output end of the constant current assembly 7021 corresponding to green; and the anode of its blue sub-laser device is connected to the current output end of the constant current assembly 7021 corresponding to blue. The common cathode of the fourth common-cathode tricolor laser device 70301 among the four series-connected common-cathode tricolor laser devices 70301 is connected to the current return end of each constant current assembly 7021. The first switch assemblies 705 in FIG. 25 are connected to the display control circuit 701, and enable signals corresponding to different colors can be transmitted to the corresponding first switch assemblies 705.

It should be noted that the series-connected structure of the plurality of common-cathode bicolor laser devices is similar to that of common-cathode tricolor laser devices, and will not be repeated here. The embodiments of the present application do not limit the number of common-cathode laser devices, which can be set according to actual conditions.

FIG. 26 is a schematic diagram of a circuit structure of a plurality of series-connected common-anode tricolor laser devices according to an embodiment of the present application. As shown in FIG. 26, by way of example, four common-anode tricolor laser devices 70302 are shown. For every two series-connected common-anode tricolor laser devices 70302: the cathode of the red sub-laser device of one common-anode tricolor laser device 70302 is connected to one end of the first switch assembly 705 corresponding to red; the cathode of the green sub-laser device is connected to one end of the first switch assembly 705 corresponding to green; the cathode of the blue sub-laser device is connected to one end of the first switch assembly 705 corresponding to blue; and the common cathode of the other common-anode tricolor laser device 70302 is connected to the other ends of the three first switch assemblies 705. For the fourth common-anode tricolor laser device 70302 among the four series-connected common-anode tricolor laser devices 70302: the cathode of the red sub-laser device is connected to the current return end of the constant current assembly 7021 corresponding to red; the cathode of the green sub-laser device is connected to the current return end of the constant current assembly 7021 corresponding to green; and the cathode of the blue sub-laser device is connected to the current return end of the constant current assembly 7021 corresponding to blue. The common anode of the first common-anode tricolor laser device 70302 among the four series-connected common-anode tricolor laser devices 70302 is connected to the current output end of each constant current assembly 7021. The first switch assemblies 705 in FIG. 26 are connected to the display control circuit 701, and enable signals corresponding to different emission colors can be transmitted to the corresponding first switch assemblies 705. It should be noted that the series-connected structure of the plurality of common-anode bicolor laser devices is similar to that of common-anode tricolor laser devices, and will not be repeated here. The embodiments of the present application do not limit the number of common-anode laser devices, which can be set according to actual conditions.

It should be noted that the first switch assembly 705 in the laser device module 703 may be a metal-oxide-semiconductor field-effect transistor (MOSFET for short). A gate of the MOSFET serves as a control end of a switch transistor, and is connected to the display control assembly for receiving the enable signal sent by the display control assembly. A source of the MOSFET is connected to the common cathode of a common-cathode tricolor laser device, the common cathode of a common-cathode bicolor laser device, the cathode of a sub-laser device in the common-anode tricolor laser device, or the cathode of a sub-laser device in a common-anode bicolor laser device. A drain of the MOSFET is connected to the anode of the sub-laser device in the common-cathode tricolor laser device, the anode of the sub-laser device in the common-cathode bicolor laser device, the common anode of the common-anode tricolor laser device, or the common anode of the common-anode bicolor laser device. When the gate of the MOSFET is at a high level, the source and the drain of the MOSFET are turned on, thereby turning on the sub-laser devices of the same emission color in the series-connected laser devices. The first switch assembly 705 in the laser device module 703 may also be a triode. A base of the triode serves as the control end of the switch transistor, and is connected to the display control assembly to receive the enable signal sent by the display control assembly. A collector of the triode is connected to the common cathode of a common-cathode tricolor laser device, the common cathode of a common-cathode bicolor laser device, the cathode of a sub-laser device in a common-anode tricolor laser device, or the cathode of a sub-laser device in a common-anode bicolor laser device. An emitter of the triode is connected to the anode of a sub-laser device in a common-cathode tricolor laser device, the anode of a sub-laser device in a common-cathode bicolor laser device, the common anode of a common-anode tricolor laser device, or the common anode of a common-anode bicolor laser device. When the base of the triode is at a high level, a base-emitter and collector of the triode are turned on, thereby turning on the sub-laser devices of the same emission color in the series-connected laser devices.

In the light source system provided in the present embodiment, the laser device module includes a plurality of laser devices and a plurality of switch assemblies. Each laser device is a common-cathode laser device or a common-anode laser device, and every two laser devices are connected through switch assemblies corresponding to each emission color in the laser devices. This design enables the series connection of common-cathode or common-anode laser devices, ensuring a consistent current across the plurality of common-cathode or common-anode laser devices and thus uniform brightness of the displayed images. The plurality of laser devices are adopted to enhance the brightness of the displayed images; meanwhile, adopting a number of constant current assemblies equal to the number of emission colors of the laser devices can effectively reduce the number of chips, lower costs, facilitate miniaturization, and reduce the generated common magnetic interference.

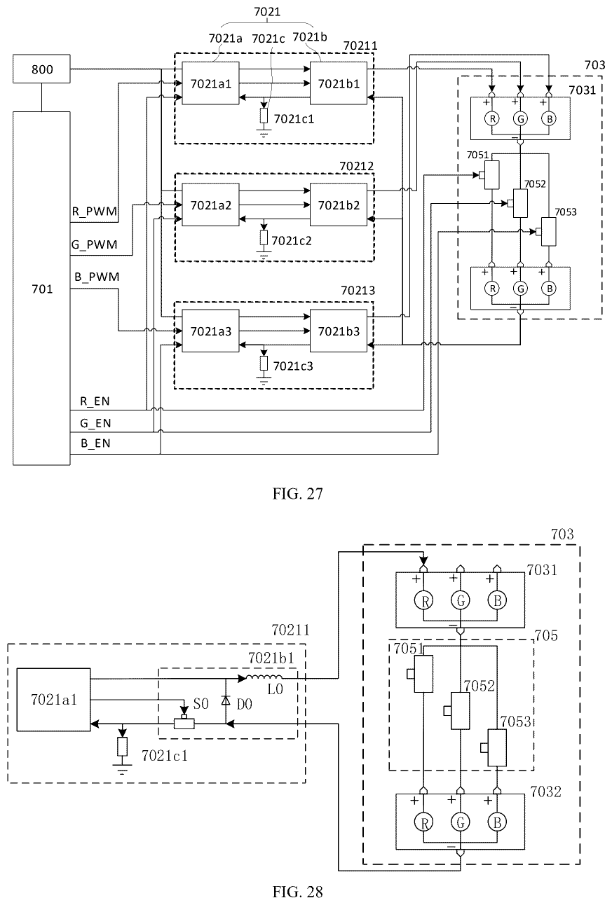

FIG. 27 is a schematic structural diagram of yet another light source system according to an embodiment of the present application. The constant current assembly 7021 is described below with reference to FIG. 27. In some embodiments, the constant current assembly 7021 includes a constant current chip 7021a, a voltage regulation assembly 7021b, and a first sampling resistor 7021c. By way of example, as shown in FIG. 27, the constant current assembly 70211 includes a constant current chip 7021a1, a voltage regulation assembly 7021b1, and a first sampling resistor 7021c1; the constant current assembly 70212 comprises a constant current chip 7021a2, a voltage regulation assembly 7021b2, and a first sampling resistor 7021c2; and the constant current assembly 70213 includes a constant current chip 7021a3, a voltage regulation assembly 7021b3, and a first sampling resistor 7021c3.

The display control circuit 701 is connected to the constant current chips 7021a in the plurality of constant current assemblies 7021 and is used to output laser drive signals (for example, PWM signals) and first enable signals to the constant current chips 7021a in the plurality of constant current assemblies 7021.

By way of example, in FIG. 27, the display control circuit 701 is connected to the constant current chip 7021a1, the constant current chip 7021a2, and the constant current chip 7021a3. The display control circuit 701 outputs a red PWM signal R_PWM to the constant current chip 7021a1, a green PWM signal G_PWM to the constant current chip 7021a2, and a blue PWM signal B_PWM to the constant current chip 7021a3, and also outputs an enable signal R_EN corresponding to red to the constant current chip 7021a1, an enable signal G_EN corresponding to green to the constant current chip 7021a2, and an enable signal B_EN corresponding to blue to the constant current chip 7021a3.

The constant current chip 7021a in the constant current assembly 7021 is connected to the voltage regulation assembly 7021b. The constant current chip 7021a and the voltage regulation assembly 7021b are connected to one end of the first sampling resistor 7021c in the constant current assembly 7021. The other end of the first sampling resistor 7021c is grounded, and the voltage regulation assembly 7021b is connected to the laser device module 703.

By way of example, in FIG. 27: the current output end of the constant current chip 7021a1 in the constant current assembly 70211 is connected to a current input end of the voltage regulation assembly 7021b1; a current output end of the voltage regulation assembly 7021b1 is connected to the anode of the red sub-laser device of the common-cathode tricolor laser device 7031 in the laser device module 703; the common cathode of the common-cathode tricolor laser device 7032 in the laser device module 703 is connected to the current return end of the voltage regulation assembly 7021b1; a current return output end of the voltage regulation assembly 7021b1 is connected to a sampling end of the constant current chip 7021a1 and one end of the sampling resistor 7021cl in the constant current assembly 70211, and the other end of the sampling resistor 7021cl is grounded. A control signal output end of the constant current chip 7021a1 is connected to the control end of the constant current assembly 70211, and the constant current chip 7021a1 outputs a control signal to the voltage regulation assembly 7021b1 through the control signal output end.

The current output end of the constant current chip 7021a2 in the constant current assembly 70212 is connected to the current input end of the voltage regulation assembly 7021b2; the current output end of the voltage regulation assembly 7021b2 is connected to the anode of the green sub-laser device of the common-cathode tricolor laser device 7031 in the laser device module 703; the common cathode of the common-cathode tricolor laser device 7032 in the laser device module 703 is connected to the current return end of the voltage regulation assembly 7021b2; the current return output end of the voltage regulation assembly 7021b2 is connected to the sampling end of the constant current chip 7021a2, and the other end of the sampling resistor 7021c2 is grounded. The control signal output end of the constant current chip 7021a2 is connected to the control end of the constant current assembly 70212, and the constant current chip 7021a2 outputs a control signal to the voltage regulation assembly 7021b2 through its control signal output end.

The current output end of the constant current chip 7021a3 in the constant current assembly 70213 is connected to the current input end of the voltage regulation assembly 7021b3; the current output end of the voltage regulation assembly 7021b3 is connected to the anode of the blue sub-laser device of the common-cathode tricolor laser device 7031 in the laser device module 703; the common cathode of the common-cathode tricolor laser device 7032 in the laser device module 703 is connected to the current return end of the voltage regulation assembly 7021b3; the current return output end of the voltage regulation assembly 7021b3 is connected to the sampling end of the constant current chip 7021a3 and one end of the sampling resistor 7021c3 in the constant current assembly 70213, and the other end of the sampling resistor 7021c3 is grounded. The control signal output end of the constant current chip 7021a3 is connected to the control end of the constant current assembly 70213, and the constant current chip 7021a3 outputs a control signal to the voltage regulation assembly 7021b3 through the control signal output end.

The constant current chip 7021a is configured to, when the received enable signal is at an effective potential, output a control signal and apply a voltage to the voltage regulation assembly 7021b based on the voltage of the received PWM signal and a sampling current obtained through the first sampling resistor 7021c; the voltage regulation assembly 7021b is configured to apply a drive voltage to the laser device module 703 based on the received control signal, thereby driving each laser device in the laser device module 703 to emit light.

By way of example, in FIG. 27, when the enable signal R_EN received by the constant current chip 7021a1 is at a high level, the constant current chip 7021a1 outputs a control signal and applies a voltage to the voltage regulation assembly 7021b1 based on the received signal R_PWM and the sampling current that is collected through the sampling end and flows out from the current return output end of the voltage regulation assembly 7021b1. The voltage regulation assembly 7021b1 adjusts the voltage applied to itself according to the received control signal to obtain a drive voltage, and then applies the drive voltage to the laser device module 703. The voltage regulation assembly 7021b1 outputs current through the current output end. The current sequentially flows through the red sub-laser device of the common-cathode tricolor laser device 7031, the first switch assembly 7051, and the red sub-laser device of the common-cathode tricolor laser device 7032, then flows back to the voltage regulation assembly 7021b1 through the current return end of the voltage regulation assembly 7021b1, and further flows into the earth through the sampling resistor 7021c1. At this point, the common cathode of the common-cathode tricolor laser device 7031 and the red sub-laser device of the common-cathode tricolor laser device 7032 are turned on and emit red light.

When the enable signal G_EN received by the constant current chip 7021a2 is at a high level, the constant current chip 7021a2 outputs a control signal and applies a voltage to the voltage regulation assembly 7021b2 based on the received signal G_PWM and the sampling current that is collected through the sampling end and flows out from the current return output end of the voltage regulation assembly 7021b2. The voltage regulation assembly 7021b2 adjusts the voltage applied to itself according to the received control signal to obtain a drive voltage, and then applies the drive voltage to the laser device module 703. The voltage regulation assembly 7021b2 outputs a current through the current output end. The current sequentially flows through the green sub-laser device of the common-cathode tricolor laser device 7031, the first switch assembly 7052, and the green sub-laser device of the common-cathode tricolor laser device 7032, then flows back to the voltage regulation assembly 7021b2 through the current return end of the voltage regulation assembly 7021b2, and further flows into the earth through the sampling resistor 7021c2. At this point, the common cathode of the common-cathode tricolor laser device 7031 and the green sub-laser device of the common-cathode tricolor laser device 7032 are turned on and emit green light.

When the enable signal B_EN received by the constant current chip 7021a3 is at a high level, the constant current chip 7021a3 outputs a control signal and applies a voltage to the voltage regulation assembly 7021b3 based on the received signal B_PWM and the sampling current that is collected through the sampling end and flows out from the current return output end of the voltage regulation assembly 7021b3. The voltage regulation assembly 7021b3 adjusts the voltage applied to itself according to the received control signal to obtain a drive voltage, and then applies the drive voltage to the laser device module 703. The voltage regulation assembly 7021b3 outputs a current through the current output end. The current sequentially flows through the blue sub-laser device of the common-cathode tricolor laser device 7031, the first switch assembly 7053, and the green sub-laser device of the common-cathode tricolor laser device 7032, then flows back to the voltage regulation assembly 7021b3 through the current return end of the voltage regulation assembly 7021b3, and further flows into the earth through the sampling resistor 7021c3. At this point, the common cathode of the common-cathode tricolor laser device 7031 and the blue sub-laser device of the common-cathode tricolor laser device 7032 are turned on and emit blue light.

By way of example, based on FIG. 27, FIG. 28 is a schematic diagram of a local circuit structure for driving the red sub-laser device according to an embodiment of the present application. As shown in FIG. 28, in some embodiments, the voltage regulation assembly 7021b1 is a Buck circuit, and the Buck circuit includes a switch assembly SO, a diode DO, and an inductor L0. A first end of the switch assembly SO is the current return output end of the voltage regulation assembly 7021b1; a second end of the switch assembly SO is connected to an anode of the diode DO, and the second end of the switch assembly SO serves as the current return end of the voltage regulation assembly 7021b1; a control end of the switch assembly SO serves as the control end of the voltage regulation assembly 7021b1. A cathode of the diode DO is connected to a first end of the inductor L0; the first end of the inductor L0 is the current input end of the voltage regulation assembly 7021b1, and a second end of the inductor L0 is the current output end of the voltage regulation assembly 7021b1. The constant current chip 7021a1 sends a control signal to the control end of the switch assembly SO. When the control signal is at an effective potential (high level), the switch assembly SO is turned on; when the control signal is at an invalid potential (low level), the switch assembly SO is turned off. By adjusting the durations of the effective potential and the invalid potential, the durations of the switch assembly SO being turned on and off can be adjusted, thereby adjusting the duty cycle and further adjusting the voltage. The Buck circuit is a step-down circuit.

This Buck circuit steps down the voltage provided by the constant current chip 7021a1 to an operating voltage of the laser device, enabling the laser device to operate normally under a constant current. It should be noted that the Buck circuit may further include a capacitor. One end of the capacitor is connected to the second end of the inductor, and the other end of the capacitor is connected to the anode of the diode. It should be noted that FIG. 28 only provides an example illustration of the voltage regulation assembly for the current for driving the red sub-laser device. When the voltage regulation assembly is a Buck circuit, other voltage regulation assemblies in the light source system are also Buck circuits, which will not be further repeated here.

By way of example, based on FIG. 27, FIG. 29 is a schematic diagram of a local circuit structure for driving the red sub-laser device according to an embodiment of the present application. As shown in FIG. 29, in some embodiments, the voltage regulation assembly 7021b1 is a Boost circuit, and the Boost circuit includes a switch assembly SO, a diode DO, and an inductor L0. A first end of the switch assembly SO is the current return output end of the voltage regulation assembly 7021b1 and also the current return end of the voltage regulation assembly 7021b1. A second end of the switch assembly SO is connected to the anode of the diode DO and a first end of the inductor L0, and a control end of the switch assembly SO is the control end of the voltage regulation assembly 7021b1. The cathode of the diode DO is the current output end of the voltage regulation assembly 7021b1, and the second end of the inductor L0 is the current input end of the voltage regulation assembly 7021b1.

The constant current chip 7021a1 sends a control signal to the control end of the switch assembly SO. When the control signal is at an effective potential (high level), the switch assembly SO is turned on; when the control signal is at an invalid potential (low level), the switch assembly SO is turned off. By adjusting the durations of the effective potential and the invalid potential, the durations of the switch assembly SO being turned on and off can be adjusted, thereby adjusting the duty cycle and further adjusting the voltage. The Boost circuit is a step-up circuit. The Boost circuit boosts the voltage provided by the constant current chip 7021a1 to the operating voltage of the laser device, enabling the laser device to operate normally under a constant current. It should be noted that the Boost circuit may further include a capacitor. One end of the capacitor is connected to the cathode of the diode, and the other end of the capacitor is connected to the first end of the switch assembly. It should be noted that FIG. 29 only provides an exemplary illustration of the voltage regulation assembly for the current driving the red sub-laser device. When the voltage regulation assembly is a Boost circuit, other voltage regulation assemblies in the light source system are also Boost circuits, which will not be repeated here.

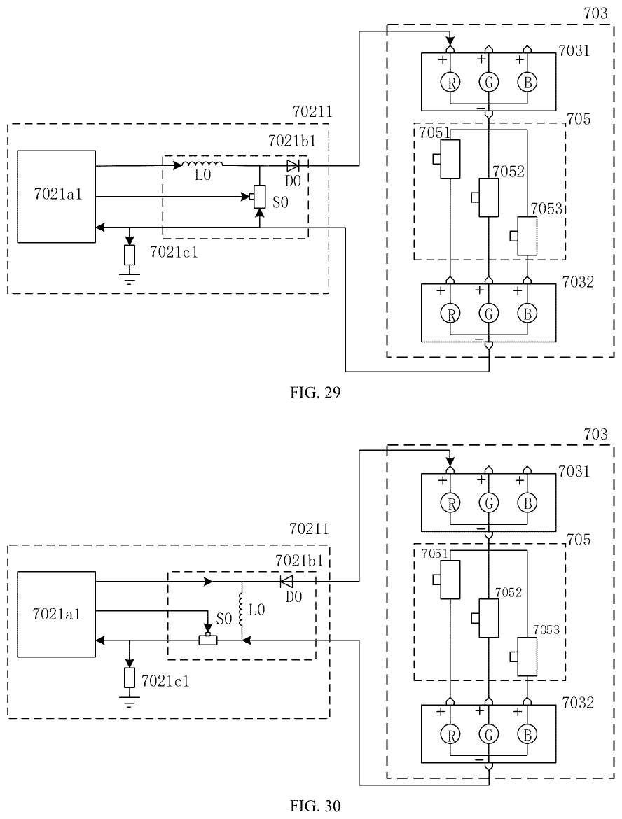

By way of example, based on FIG. 27, FIG. 30 is a schematic diagram of a local circuit structure for driving the red sub-laser device according to an embodiment of the present application. As shown in FIG. 30, in some embodiments, the voltage regulation assembly 7021b1 is a Buck-Boost circuit, and the Buck-Boost circuit includes a switch assembly SO, a diode DO, and an inductor L0. A first end of the switch assembly SO is the current return output end of the voltage regulation assembly 7021b1, a second end of the switch assembly SO is connected to the first end of the inductor L0, the second end of the switch assembly SO is the current return end of the voltage regulation assembly 7021b1, and a control end of the switch assembly SO is the control end of the voltage regulation assembly 7021b1. The second end of the inductor L0 is connected to the cathode of the diode DO, the cathode of the diode DO is the current input end of the voltage regulation assembly 7021b1, and the anode of the diode DO is the current output end of the voltage regulation assembly 7021b1.

The constant current chip 7021a1 sends a control signal to the control end of the switch assembly SO. When the control signal is at an effective potential (high level), the switch assembly SO is turned on; when the control signal is at an invalid potential (low level), the switch assembly SO is turned off. By adjusting the durations of the effective potential and the invalid potential, the durations of the switch assembly SO being turned on and off can be adjusted, thereby adjusting the duty cycle and further adjusting the voltage. The Buck-Boost circuit can both boost and buck the voltage. When the voltage provided by the constant current chip 7021a1 is different from the operating voltage of the laser device, the Buck-Boost circuit adjusts the voltage provided by the constant current chip to the operating voltage of the laser device, enabling the laser device to operate normally under a constant current. It should be noted that the Buck-Boost circuit may further include a capacitor. One end of the capacitor is connected to the anode of the diode, and the other end of the capacitor is connected to the second end of the switch transistor. It should be noted that FIG. 30 only provides an exemplary illustration of the voltage regulation assembly for the current driving the red sub-laser device. When the voltage regulation assembly is a Buck-Boost circuit, other voltage regulation assemblies in the light source system are also Buck-Boost circuits, which will not be repeated here.

It should be noted that the switch transistor in the voltage regulation assembly may be a MOSFET, a triode, or an electronic device or a circuit that can be turned on and off according to the level of the control signal. The embodiment of the present application does not limit the switch transistor in the voltage regulation assembly, which can be set according to actual conditions.

The light source system provided in this embodiment can accurately control the value of the current flowing into the plurality of laser devices through the constant current chip and the voltage regulation assembly in the constant current assembly, maintain a stable current, and also adjust the voltage to ensure that the laser device operates at the operating voltage, thus ensuring the safe operation of the light source system. In addition, there are a small number of constant current assemblies used in this scheme, as well as a small number of switch assemblies, which can effectively reduce costs, occupied volume, energy loss, and common magnetic interference.

An embodiment of the present application further provides a light source system, which includes a display control circuit 701, a laser drive chip 702, and a laser device module 703. the laser drive chip 702 includes a plurality of constant current assemblies 7021, and the plurality of constant current assemblies 7021 are connected to the laser device module 703. The display control circuit 701 is connected to the plurality of constant current assemblies 7021, respectively, and is configured to output laser drive signals (such as dimming analog signals or pulse width modulation signals) and first enable signals to the plurality of constant current assemblies 7021; the laser device module 703 includes a plurality of laser devices and a plurality of first switch assemblies 705, the plurality of laser devices are common-cathode laser devices or common-anode laser devices, and the plurality of laser devices are connected through a plurality of first switch assemblies 705. The display control circuit 701 is connected to the plurality of first switch assemblies 705, respectively, and is configured to output second enable signals to the plurality of first switch assemblies 705.

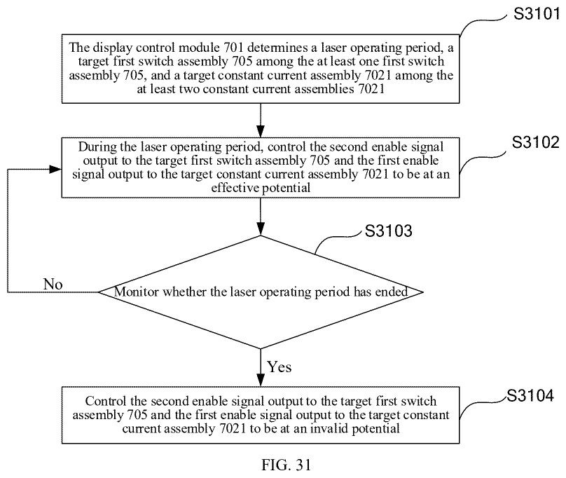

FIG. 31 is a flowchart of a laser device control method provided by the present application. As shown in FIG. 31, in some embodiments, the laser device control method includes the following steps:
S3101: The display control circuit 701 determines a laser operating period, a target first switch assembly 705 among the plurality of first switch assemblies 705, and a target constant current assembly 7021 among the plurality of constant current assemblies 7021. In this step, to display an image, each sub-laser device in the laser device is turned on during the laser operating period within one cycle. Therefore, the display control circuit 701 needs to obtain the operating period, the target first switch assembly 705 among the plurality of first switch assemblies 705, and the target constant current assembly 7021 among the plurality of constant current assemblies 7021.
S3102: During the laser operating period, the display control circuit controls the second enable signal output to the target first switch assembly 705 and the first enable signal output to the target constant current assembly 7021 to be at an effective potential. In this step, after the display control circuit 701 obtains the operating period, the target first switch assembly 705, and the target constant current assembly 7021; and during the laser operating period, the display control circuit controls the enable signals output to the target first switch assembly 705 and the target constant current assembly 7021 to be at an effective potential. When the received second enable signal is at an effective potential, the target first switch assembly 705 switches to an on state, turning on two laser devices connected to the target first switch assembly 705. When the received first enable signal is at an effective potential, the target constant current assembly 7021 applies a drive voltage to the laser device module 703 according to the laser drive signal (such as a PWM signal) and outputs a current to the laser device module 703. The current flows through a target sub-laser device (or target laser light source) of each laser device in the laser device module 703 and the target first switch assembly 705, and then flows back to the target constant current assembly 7021, and the target sub-laser device emits light.
S3103: The display control circuit monitors whether the laser operating period has ended; if it is monitored that the laser operating period has not ended, execute step S1702; and if it is monitored that the laser operating period has ended, execute steps S1704.
S3104: The display control circuit controls the enable signals output to the target switch assembly and the target constant current assembly to be at an invalid potential. In the above steps, the display control assembly monitors whether the laser operating period has ended; if it is monitored that the laser operating period has not ended, it indicates that it is still within the laser operating period and the laser device needs to operate, then execute step S3102; if it is monitored that the laser operating period has ended, the display control assembly controls the enable signals output to the target first switch assembly 705 and the target constant current assembly 7021 to be at an invalid potential (low potential, also referred to as low level) when the laser operating period ends. When the received enable signal is at an invalid potential, the target first switch assembly 705 switches to an off state, turning off the two laser devices connected to the target first switch assembly 705. When the received enable signal is at an invalid potential, the target constant current assembly 7021 stops applying the drive voltage to the laser device module 703 and stops outputting the current to the laser device module 703, and the target sub-laser device in the laser device module 703 is turned off.

In the light source system provided by the present application, a laser device module 703 includes a plurality of laser devices and a plurality of first switch assemblies. The laser devices are common-cathode laser devices or common-anode laser devices, and the two laser devices are connected through the first switch assembly, which can achieve the series connection of common-cathode laser devices or common-anode laser devices, ensure that the currents of the plurality of common-cathode laser devices or the currents of the plurality of common-anode laser devices are consistent, and thus the brightness of the displayed image is consistent; using a plurality of laser devices makes the brightness of the displayed image higher; it can also effectively reduce the number of chips, reduce costs, facilitate miniaturization, and reduce the generated common magnetic interference.

Those of ordinary skill in the art can understand that all or part of the steps for implementing the above method embodiments can be completed by hardware related to program instructions. The aforementioned program can be stored in a computer-readable storage medium. When the program is executed, the steps including the above method embodiments are executed; and the aforementioned storage medium includes various media that can store program codes, such as ROM, RAM, magnetic disks, or optical disks.

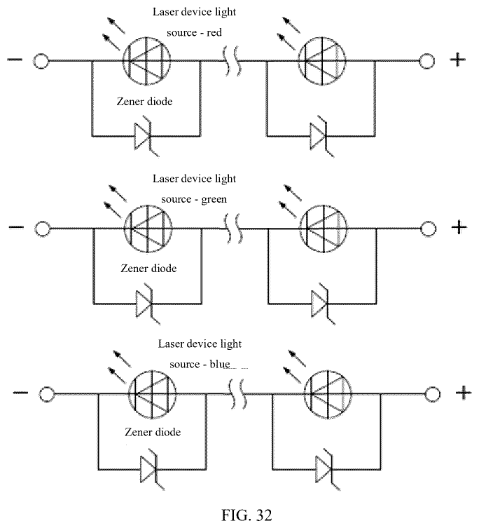

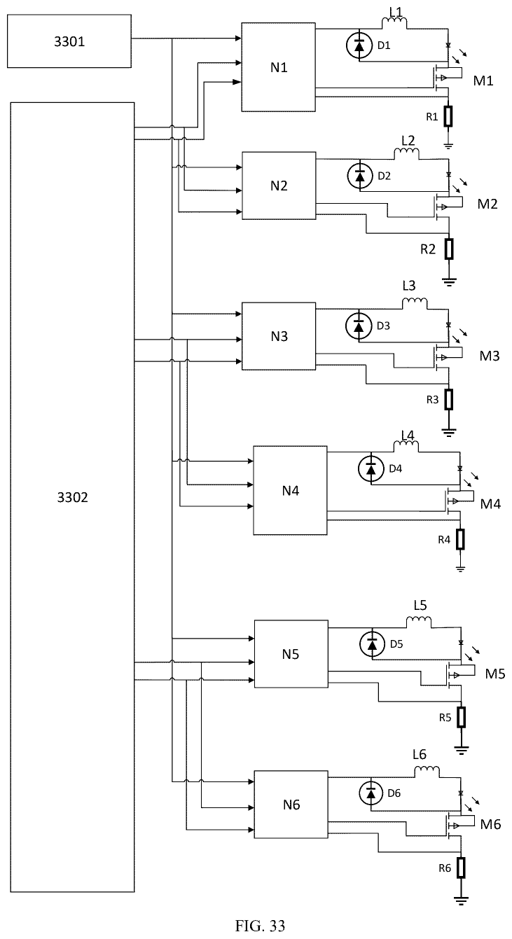

FIG. 32 is a schematic diagram of a circuit structure of a tricolor laser device provided in the related art. As shown in FIG. 32, the laser devices of three colors (red, green, and blue) each need to correspond to two pins, i.e., the tricolor laser device needs at least 6 pins. FIG. 33 is a schematic diagram of a circuit structure of a light source system provided in the related art. As shown in FIG. 33, after the light source system is turned on, a projection display control processing unit 3302 of the light source system (which may include a digital light processing (DLP) display chip, for example) can, after initialization, use three groups of general-purpose input/output (GPIO) to control the enable (EN) signals of six constant current integrated circuits (IC) according to a set duty timing sequence, and control the brightness of each laser device through three groups of dimming pins.

As shown in FIG. 33, when driving the two laser devices, the light source system of the related art needs at least 6 constant current IC chips (such as N1, N2, N3, N4, N5, N6 shown in FIG. 33), 6 inductors (such as L1, L2, L3, L4, L5, L6 shown in FIG. 33), 6 metal-oxide-semiconductor field-effect transistors (MOSFETs, referred to as MOSFETs for short) (such as M1, M2, M3, M4, M5, M6 shown in FIG. 33), 6 diodes (such as D1, D2, D3, D4, D5, D6 shown in FIG. 33), and 6 groups of current sampling resistors (such as R1, R2, R3, R4, R5, R6 shown in FIG. 33).

Therefore, the light source system provided in the related art has the following technical problems: 1. Due to problems such as the factory precision of current sampling resistors, there is a current difference between two laser devices of the same color in a parallel circuit, and the current difference will cause a difference in the luminous flux of the laser devices, thereby leading to a difference in image display, resulting in poor user experience. 2. Because a large number of components are required, such as at least 6 channels of constant current IC chips, 6 custom inductors, 6 MOSFETs, etc., the occupied area of the laser device is still large. 3. Because 6 channels of MOSFET switches generate a lot of heat due to switching loss, conduction loss, etc., the laser device also needs a large heat sink, which further increases the occupied area of the laser device. 4. When 6 channels of MOSFETs perform constant current regulation, frequent turning-on or turning-off will generate a lot of electromagnetic radiation, leading to electromagnetic compatibility (EMC) problems, which in turn requires adding magnetic rings or components for shielding to solve EMC problems in the later stage, further increasing the occupied area of the laser device.

That is, the laser device of an existing light source system still has the problems of a large occupied area and poor user experience.

Considering the above problems existing in the existing light source system, the present application proposes a light source system that connects a plurality of laser devices through a switch module to ensure that the intensity of the drive signal flowing through different laser devices is the same. Through the light source system, the intensity of the drive signal flowing through a plurality of laser devices of the same color is the same, thereby reducing the difference in image display and improving the user experience. For the above laser device, the light source system provided by the present application can control the number of laser devices to be turned on with fewer components, reduce the occupied area of the light source system, and further realize the miniaturization of the light source system.

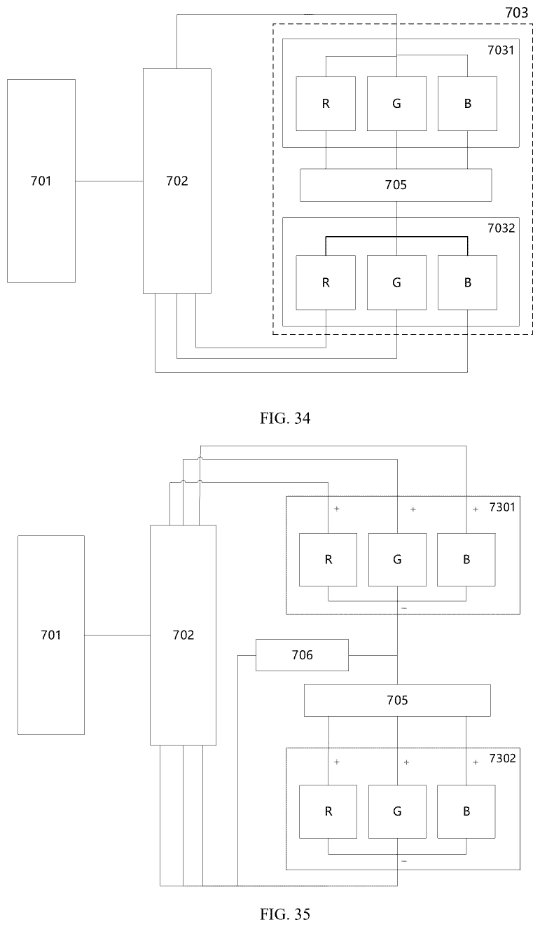

FIG. 34 is a schematic diagram of a circuit structure of yet another light source system according to an embodiment of the present application. As shown in FIG. 34, in some embodiments, the light source system may include: a display control circuit 701, a driving device, and N laser devices. Each laser device may include laser light sources of i colors, and the laser light sources of the i colors correspond to the same anode or the same cathode. Both N and i are integers greater than or equal to 2. The driving device may include: a first switch assembly 705 and a laser drive chip 702. The N laser devices may be connected through the first switch assembly 705. It should be understood that the laser device, including i laser light sources (or sub-laser devices) in the present application, can also be understood as a light source module including laser devices of i colors, which are only different in name but the same in essence.

The schematic structural diagram of the light source system involved anywhere in the present application is an exemplary description of the structure of the light source system by taking the light source system including two laser devices, and each laser device including a red laser light source, a green laser light source, and a blue laser light source as an example. The present application does not limit the number of laser devices included in the light source system, the number of laser light sources included in each laser device, and the colors of light beams emitted by the laser light sources included in the laser device. In addition, it should be understood that FIG. 34 only provides an exemplary description of the light source system by taking the laser light sources of i colors corresponding to the same anode as an example. As mentioned above, the laser light sources of the i colors may also correspond to the same cathode.

By way of example, the display control circuit 701 may be a System on Chip (SOC) or the aforementioned DLP, etc. In some embodiments, the display control circuit 701 may also be referred to as a display control processing unit. The display control circuit 701 may be configured to output first enable signals corresponding to i colors to the laser drive chip 702, and output second enable signals corresponding to i colors to the first switch assembly 705. By way of example, the display control circuit 701 may output the first enable signal to the laser drive chip 702 and the second enable signal to the first switch assembly 705 according to a preset timing signal used to represent a lighting sequence of the laser light sources.

For any color, the laser drive chip 702 may be configured to output a drive signal to the laser device of the color when the first enable signal corresponding to the color is at a target value. The first switch assembly 705 may be configured to turn on the laser light sources of the color when the second enable signal corresponding to the color is at a target value, so that the laser light sources of the color receive the drive signal to be turned on.

Optionally, the drive signal may be a drive current or a drive voltage, etc., which is not limited in the present application. By way of example, taking the first enable signal as a level signal, the target value may be an effective level of the first enable signal.

In the present embodiment, the N laser devices are connected through the first switch assembly 705, so that the laser light sources of the same color among the N laser devices can be turned on through the first switch assembly 705, and thus the signal intensity of the drive current from the laser drive chip 702 applied to different laser light sources of the same color can be the same. Therefore, the difference in luminous flux between the laser light sources can be reduced, thereby reducing the difference in image display and improving the user experience. Through the light source system provided by the present application, the laser light sources of i colors included in the laser device may correspond to the same anode or the same cathode. Through the above method, the number of pins to be deployed for the laser device is reduced, thereby reducing the space required for the laser device, so the space occupied by the light source system can be reduced, and the miniaturization of the light source system is realized.

As shown in FIG. 35, in some embodiments, the driving device may further include a second switch assembly 706. In this implementation manner, the display control circuit 701 may also be configured to output a third enable signal to the second switch assembly 706. The second switch assembly 706 may be turned on when the third enable signal is at a second value, so that the laser light sources in at least one target laser device among the N laser devices do not receive the drive current. By way of example, taking the drive signal as a drive current, when the second switch assembly 706 is turned on in response to the second value of the second enable signal, for example, the target laser device may be short-circuited, so that the laser light sources in the target laser device cannot receive the drive current.

When the laser light sources in the target laser device do not receive the drive signal, the laser light sources in the target laser device will not be turned on. Optionally, in this implementation manner, the light source system may continue to perform projection display through a plurality of laser light sources in the laser devices other than the target laser device among the N laser devices. By way of example, the display control circuit 701 may control a plurality of laser light sources in the “laser devices other than the target laser device among the N laser devices” to be turned on simultaneously for laser projection display through the laser drive chip 702, so as to improve the display brightness of the laser device.

In this embodiment, through the second switch assembly 706, it is possible to control the laser light sources in at least one target laser device among the N laser devices not to receive the drive signal, so that the light source system may not perform projection display through the laser light sources in the target laser device.

The following takes N equal to 2 and i greater than 2 as an example to exemplarily describe the connection manner of the second switch assembly 706 in the light source system:

Taking the laser light sources of i colors included in the laser device corresponding to the same cathode as an example, FIG. 35 is a schematic structural diagram of yet another light source system according to an embodiment of the present application. As shown in FIG. 35, in some embodiments, a first end of the second switch assembly 706 may be connected to the display control circuit 701 (it should be understood that it is not shown in FIG. 35). A second end of the second switch assembly 706 may be connected to the cathodes of the laser light sources of i colors included in the laser devices other than the target laser device. A third end of the second switch assembly 706 may be connected to the cathodes of the laser light sources of i colors included in the target laser device. In FIG. 35, the common-cathode tricolor laser device 7032 is the target laser device, and the common-cathode tricolor laser device 7031 is the laser device other than the target laser device.

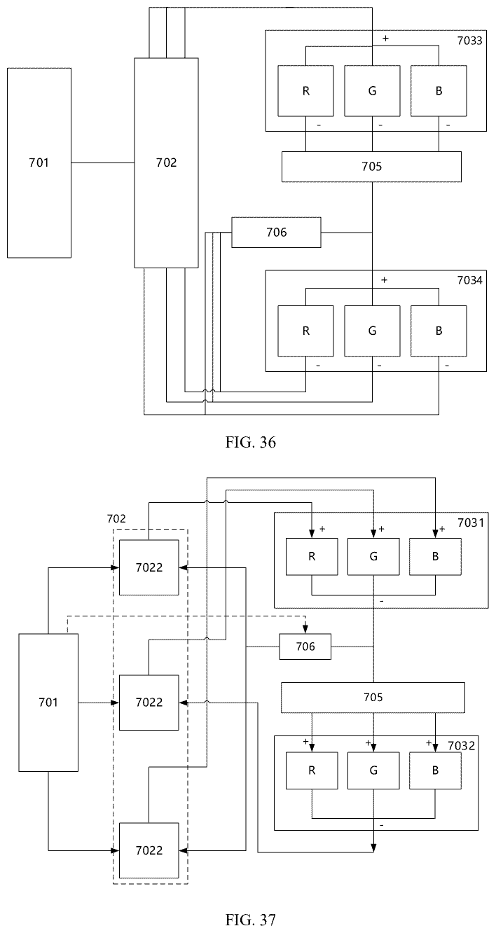

Taking the laser light sources of i colors included in the laser device corresponding to the same anode as an example, FIG. 36 is a schematic structural diagram of yet another light source system according to an embodiment of the present application. As shown in FIG. 36, in some embodiments, a first end of the second switch assembly 706 may be connected to the display control circuit 701 (it should be understood that it is not shown in FIG. 36). The second end of the second switch assembly 706 may be connected to the anodes of the laser light sources of i colors included in the target laser device; the third end of the second switch assembly 706 may be connected to the cathodes of the laser light sources of i colors included in the target laser device.

The target laser device may be one of the 2 laser devices included in the light source system. The laser device other than the target laser device may be the other one of the 2 laser devices included in the light source system. By way of example, the second switch assembly 706 may include at least one switching device. It should be understood that the present application does not limit the type of the switching device. For example, the switching device may be a MOSFET. In FIG. 36, the common-anode tricolor laser device 7034 is the target laser device, and the common-anode tricolor laser device 7033 is the laser device other than the target laser device.

The following exemplarily describes the timing when the light source system controls the second switch assembly 706 to be turned on:

In some embodiments, the display control circuit 701 may also be configured to receive an instruction to convert the brightness level to a target brightness level. In this implementation manner, the display control circuit 701 may respond to the instruction and output the third enable signal at the second value to the second switch assembly 706, so that the second switch assembly 706 is turned on.

By way of example, the instruction to convert the brightness level to the target brightness level may be an instruction to turn on an overlap function of the light source system. The target brightness level may be pre-stored in the display control circuit 701, for example. By way of example, the light source system may receive an instruction input by the user to select the target brightness level for display through the display control circuit 701 via a brightness level setting interface, as an instruction to convert the brightness level to the target brightness level.

Through the above method, the light source system can respond to the user's operation of setting the brightness level of the light source system, and realize the switching of the brightness level through the turning on and off of the second switch assembly 706, which improves the flexibility of the light source system and the user experience.

In some embodiments, the display control circuit 701 may also receive a laser light source fault notification from the laser drive chip 702, for example. In this implementation manner, the display control circuit 701 may respond to the laser light source fault notification and output the second enable signal at the second value to the second switch assembly 706, so that the second switch assembly 706 is turned on.

Optionally, the present application does not limit how the laser drive chip 702 determines whether the laser light source is faulty. By way of example, the laser drive chip 702 may, for example, integrate any existing function of determining whether the laser light source is faulty, which is not limited by the present application. In addition, it should be understood that the present application also does not limit how the display control circuit 701 receives the laser light source fault notification from the laser drive chip 702. For example, taking the laser drive chip 702 also including a fault pin as an example, the display control circuit 701 may, for example, also be connected to the fault pin of the laser drive chip 702. When detecting a laser light source fault, the laser drive chip 702 may, for example, send the laser light source fault notification to the display control circuit 701 via the fault pin.

Through the above method, when receiving the laser light source fault notification, the display control circuit 701 may output the second enable signal at the second value to the second switch assembly 706 to turn on the second switch assembly 706, thereby preventing the laser light sources in at least one target laser device among the N laser devices from receiving the drive signal. Then, the display control circuit 701 can locate the specific faulty laser light source based on whether there is still a laser light source fault after the laser light sources in the target laser device do not receive the drive signal, realizing automatic fault detection of the light source system and further improving the flexibility of the light source system.

Taking N equal to 2, i greater than 2, and the laser drive chip 702 including i drive units 7022 in one-to-one correspondence with the i colors as an example, FIG. 37 is a schematic structural diagram of yet another light source system according to an embodiment of the present application. As shown in FIG. 37, in some embodiments, for any color, one end of the drive unit 7022 may be connected to the anode of the laser light source of the color, and the other end may be connected to the cathode of another laser light source of the color. In some embodiments, after the second switch assembly 706 is turned on, if the display control circuit 701 receives laser light source fault prompt-free information from the target drive unit 7022, it indicates that the fault is eliminated after the target laser device does not receive the drive signal, the display control circuit 701 can determine that the fault of the laser light source of the color corresponding to the target drive unit 7022 in the target laser device causes the laser light source fault notification. That is, the laser light source of the corresponding color in the common-cathode laser device 7032 in FIG. 37 is faulty, and the laser light source of the corresponding color in the common-cathode laser device 7031 is not faulty. The display control circuit 701 may also continue to output the third enable signal at the second value to the second switch assembly 706, so that the faulty target laser device does not receive the drive signal, avoiding using the faulty target laser device for projection display, and thus performing image display through the fault-free laser device (i.e., the laser device other than the target laser device among the N laser devices).

Optionally, the target drive unit 7022 may be any one of the i drive units 7022.

Optionally, after enabling the target laser device not to receive the drive signal and only performing image display through the laser device other than the target laser device among the N laser devices, the brightness of the light source system may decrease. Therefore, the light source system, for example, may also output prompt information to prompt the user that the target laser device is faulty.

Through the above method, the faulty target laser device can be automatically detected and determined, and no drive signal is output to the faulty target laser device. Only the laser device other than the target laser device among the fault-free N laser devices is used for image display. Thus, even if one laser device is faulty, the light source system can automatically switch to perform image display through a fault-free laser device, thereby improving the user experience.

If the display control circuit 701 receives a laser light source fault notification from the target drive unit 7022, it indicates that the laser light source fault is still not resolved after the target laser device does not receive the drive signal. Therefore, it indicates that the faulty laser light source is not in the target laser device. That is, the laser light source of the corresponding color in the common-cathode laser device 7031 in FIG. 37 is faulty. Then the display control circuit 701 can determine that the laser light source of the color corresponding to the drive unit 7022 in the laser device other than the target laser device among the N laser devices is faulty, and turn off the light source system.

By way of example, the light source system may also prompt a fault through an indicator light.

Through the above method, the faulty laser device can be automatically detected and determined, improving the fault detection efficiency and further improving the user experience.

The following exemplarily describes the structures of the laser drive chip 702 and the first switch assembly 705:

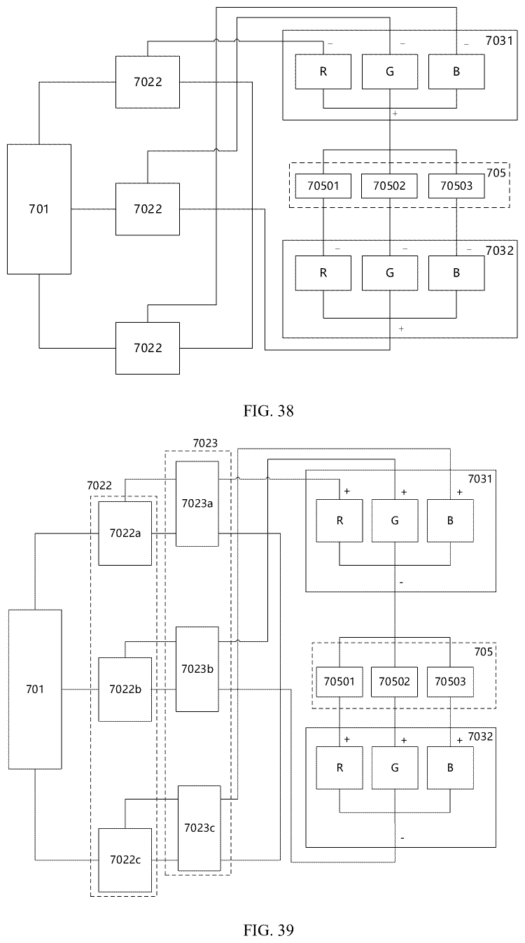

FIG. 38 is a schematic structural diagram of yet another light source system according to an embodiment of the present application. As shown in FIG. 38, in some embodiments, the laser drive chip 702 may include: i drive units 7022 in one-to-one correspondence with the i colors. The first switch assembly 705 may include: i first switch units in one-to-one correspondence with the i colors, such as a first switch unit 70501, a first switch unit 70502, and a first switch unit 70502 in FIG. 38. By way of example, the first switch unit 70501 corresponds to red, the first switch unit 70502 corresponds to green, and the first switch unit 70502 corresponds to blue.

For any color, among the N laser devices, the N laser light sources of the color are connected through the first switch unit corresponding to the color to form a light-emitting module of the color. The first end of the drive unit 7022 corresponding to the color is connected to a first end of the light-emitting module, and the second end of the drive unit corresponding to the color is connected to a second end of the light-emitting module. The display control circuit 701 is connected to the first switch unit (it should be understood that the connection relationship between the display control circuit 701 and the first switch unit is not shown in FIG. 8) and a third end of the drive unit 7022. Each light-emitting module corresponds to one color. Taking the light source system shown in FIG. 38 as an example, the red laser light source R in the common-cathode laser device 7031 and the red laser light source R in the common-cathode laser device 7032 form a red light-emitting module, the green laser light source G in the common-cathode laser device 7031 and the green laser light source G in the common-cathode laser device 7032 form a green light-emitting module, and the blue laser light source B in the common-cathode laser device 7031 and the blue laser light source B in the common-cathode laser device 7032 form a blue light-emitting module.

By way of example, by taking the laser device as a tricolor laser device as an example, the laser drive chip 702 may include: 3 drive units 7022. The 3 drive units 7022 may be in one-to-one correspondence with the 3 colors. By way of example, the drive unit 7022, for example, may be the constant current IC. Taking the drive unit 7022 as a constant current IC as an example, when the laser device is a tricolor laser device, compared with the manner that 6 constant current ICs are needed to drive parallel tricolor laser devices in the related art, the present application only needs 3 constant current ICs, reducing the number of devices for controlling the laser device to be turned on, thereby reducing the space occupied by the light source system. By way of example, the first switch unit may include at least one switching device. It should be understood that the present application does not limit the type of the switching device. For example, the switching device may be a MOSFET.

As mentioned above, the driving device can realize the brightness adjustment of the light source system by adjusting the magnitude of the drive current input to the laser light source. The following exemplarily describes how the driving device performs current regulation:

As shown in FIG. 35, in some embodiments, taking the light source system including a first laser device and a second laser device, and both the first laser device and the second laser device being common-cathode laser devices as an example, the light source system includes a first switch assembly 705 and a second switch assembly 706; the anode of each laser light source in the second laser device is connected to the first end of the corresponding first switch assembly 705; second ends of all the first switch assemblies 705 connected to the second laser device are respectively connected to a common cathode of the first laser device and a first end of the second switch assembly 706, and a second end of the second switch assembly 706 is connected to a common cathode of the second laser device. Thus, the light source system can use the first switch assembly 705 to control the on-off of the laser light sources of the same color in the adjacent first laser device and second laser device, and use the second switch assembly 706 to control whether the second laser device can receive the drive current.

As shown in FIG. 36, in some embodiments, taking the light source system including a third laser device and a fourth laser device, and both the third laser device and the fourth laser device being common-anode laser devices as an example, the light source system includes a first switch assembly 705 and a second switch assembly 706; a cathode of each laser light source in the third laser device is connected to a first end of the corresponding first switch assembly 705; second ends of all the first switch assemblies 705 connected to the third laser device are respectively connected to a common anode of the fourth laser device and a first end of the second switch assembly 706, and a second end of the second switch assembly 706 is connected to a cathode of each laser light source in the third laser device. Thus, the light source system can use the first switch assembly 705 to control the on-off of the laser light sources of the same color in the adjacent first laser device and second laser device, and use the second switch assembly 706 to control whether the second laser device can receive the drive current.

In some embodiments, the driving device may further include: a current regulation module. FIG. 39 is a schematic structural diagram of yet another light source system according to an embodiment of the present application. As shown in FIG. 39, by way of example, the current regulation module may include i current regulation units 7023 in one-to-one correspondence with the i colors, such as a current regulation unit 7023a, a current regulation unit 7023b, and a current regulation unit 7023c in FIG. 39. By way of example, the current regulation unit 7023a corresponds to red, the current regulation unit 7023b corresponds to green, and the current regulation unit 7023c corresponds to blue. In addition, FIG. 39 also shows i drive units 7022 in one-to-one correspondence with the i colors, including a drive unit 7022a corresponding to red, a drive unit 7022b corresponding to green, and a drive unit 7022c corresponding to blue.

For any color, the first end of the laser drive chip 702 corresponding to the color may be connected to the first end of the current regulation unit 7023 corresponding to the color. A second end of the current regulation unit 7023 may be connected to the first end of the light-emitting module. A third end of the current regulation unit 7023 may be connected to the second end of the light-emitting module. A fourth end of the current regulation unit 7023 may be connected to a fourth end of the drive unit 7022 corresponding to the color.

Taking the control signal including an enable signal and a dimming signal as an example, in this implementation manner, the drive unit 7022 may be configured to respond to the enable signal and control the magnitude of the drive current output by the current regulation unit 7023 to the light-emitting module based on the dimming signal from the display control circuit 701.

Through the above current regulation module, the driving device can adjust the magnitude of the current output to the laser light source, thereby realizing the brightness adjustment of the light source system. The number of the current regulation units may be the same as the number of colors of the laser light sources included in the laser device. That is to say, taking a tricolor laser device as an example, the light source system provided by the present application only needs three current regulation units. Compared with the method of using six sets of the same components for current regulation in the related art, the light source system further reduces the number of components, and the space occupied by the light source system is reduced, thus further achieving the miniaturization of the light source system.

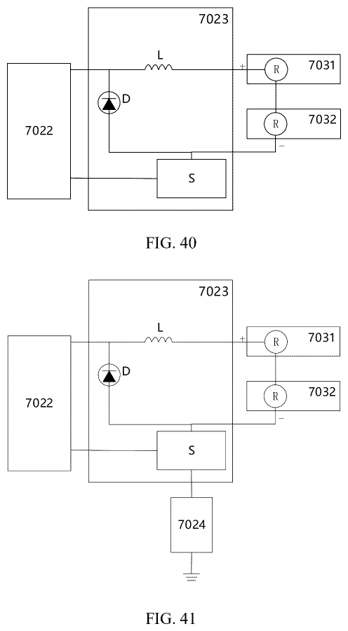

FIG. 40 is a schematic structural diagram of a current regulation unit according to an embodiment of the present application. As shown in FIG. 40, in some embodiments, the current regulation unit may include: an inductor L, a diode D, and a third switch assembly S. A first end of the inductor L may be connected to the first end of the drive unit 7022 corresponding to the color and a cathode of the diode D. A second end of the inductor L may be connected to the first end of the light-emitting module (such as the laser device 7031 in FIG. 40). A first end of the third switch assembly S may be connected to the second end of the light-emitting module (such as the laser device 7032 in FIG. 40) and an anode of the diode D. A second end of the third switch assembly S may be connected to the fourth end of the drive unit 7022 corresponding to the color.

By way of example, the inductor may refer to an energy storage inductor in any existing current regulation unit, which is not limited by the present application. The diode may be a Zener diode. The third switch assembly S may include at least one switching device. By way of example, the switching device may be a MOSFET, etc., which is not limited by the present application.

Optionally, for any driving device, the drive unit, the third switch assembly, the diode, and the inductor included in the driving device may form a Buck structure. The Buck structure may be used to reduce the input voltage to a voltage level suitable for the operation of the laser device. Optionally, the specific implementation manner of the Buck structure may refer to any existing implementation method, which will not be repeated here.

Through the above current regulation unit, taking a tricolor laser device as an example, the light source system only needs to control the tricolor laser device based on three current regulation units, which correspondingly means that only three inductors, three diodes, etc., are needed. Therefore, compared with the implementation manner in the related art that requires 6 inductors and 6 diodes to control the tricolor laser device, the present application further reduces the number of components, reduces the space occupied by the light source system, and thus further realizes the miniaturization of the light source system.

In some embodiments, the driving device may further include a sampling module. The sampling module may include i second sampling resistors 7024 in one-to-one correspondence with the i colors. FIG. 41 is a schematic structural diagram of another current regulation unit according to an embodiment of the present application. As shown in FIG. 41, optionally, for any color, a third end of the third switch assembly S is grounded through the second sampling resistor 7024 corresponding to the color.

It should be understood that the present application does not limit the resistance value of the second sampling resistor 7024. The resistance values of the second sampling resistors 7024 corresponding to different colors may be the same or different, which is not limited by the present application.

Through the above method, still taking a tricolor laser device as an example, the light source system only needs to include three second sampling resistors. Compared with the implementation manner in the related art that requires 6 sampling resistors to control the tricolor laser device, the present application further reduces the number of components, reduces the space occupied by the light source system, thereby further achieving the miniaturization of the light source system.

The following takes the light source system including two tricolor laser devices as an example to exemplarily describe the light source system provided by the present application:

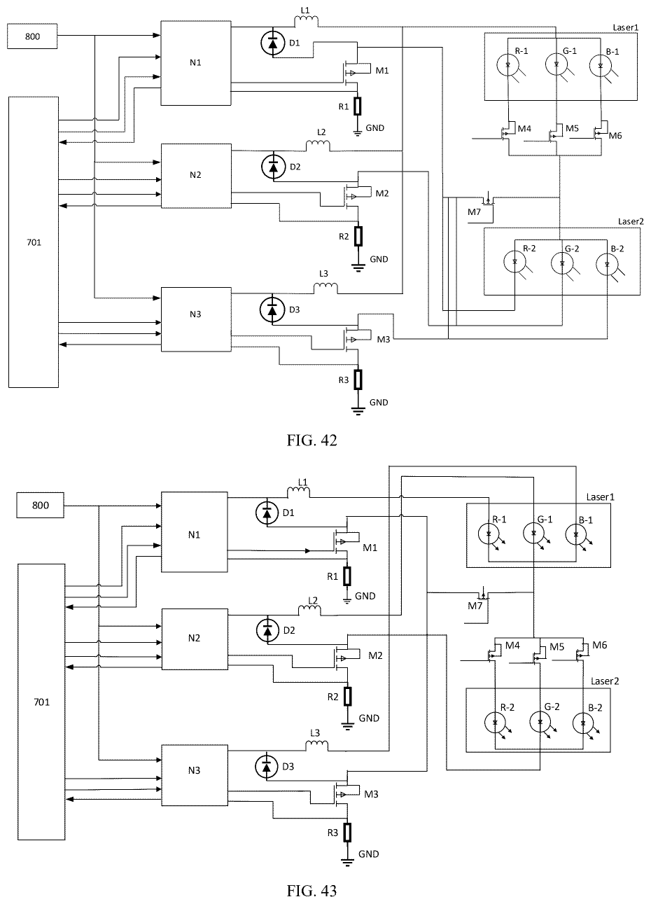

Taking the common-anode three-color laser devices as an example, FIG. 42 is a schematic structural diagram of yet another light source system according to an embodiment of the present application. Taking the common-cathode tricolor laser devices as an example, FIG. 43 is a schematic structural diagram of yet another light source system according to an embodiment of the present application. As shown in FIG. 42 and FIG. 43, the constant current ICs (N1, N2, and N3) may also be connected to an AC-DC power supply 800 via VCC pins.

As shown in FIG. 42 and FIG. 43, the display control circuit 701 may be a DLP or an SOC. The drive unit may be a constant current IC, for example. The display control circuit 701 may output a dimming signal (i.e., the laser drive signal) to the constant current IC via the Dimming pin of the constant current IC, and output an enable signal via the EN pin (i.e., an enable pin) of the constant current IC. The constant current IC may feed back prompt information to the display control circuit 701 on whether the laser light source is faulty via a fault pin (i.e., a fault signal feedback pin).

The third switch assembly S may be, for example, the MOSFET M1, the MOSFET M2, and the MOSFET M3 shown in FIG. 42 and FIG. 43. The constant current IC may be connected to the third switch assembly S through a DRV pin, and output a MOS drive signal to the third switch assembly S via the DRV pin to control the on or off of the third switch assembly S. The diode D included in the current regulation unit 7023 may be, for example, D1, D2, D3 shown in FIG. 42 and FIG. 43, and the inductor L may be L1, L2, L3 shown in FIG. 42 and FIG. 43. The second sampling resistor 7024 may be, for example, the resistors R1, R2, R3 shown in FIG. 42 and FIG. 43; the constant current IC may be connected to the second sampling resistor 7024 via an FB (signal feedback) pin. GND denotes ground. Laser1 and Laser2 represent laser devices, R-1 represents the red laser device of the laser device Laser1, G-1 represents the green laser device of the laser device Laser1, B-1 represents the blue laser device of the laser device Laser1; R-2 represents the red laser device of the laser device Laser2, G-2 represents the green laser device of the laser device Laser2, and B-2 represents the blue laser device of the laser device Laser2. The first switch unit may be, for example, MOSFETs M4, M5 and M6 shown in FIG. 42 and FIG. 43. The second switch assembly 706 may be, for example, a MOSFET M7.

In some embodiments, the light source system comprises a first switch assembly 705, a second switch assembly 706, and a third switch assembly S; the first switch assembly 705, the second switch assembly 706, or the third switch assembly S is at least one of a triode and a metal-oxide-semiconductor field-effect transistor (MOSFET).

Taking the application of the light source system to a laser TV as an example, based on the light source system shown in FIG. 42 and FIG. 43, in some embodiments, by controlling the timing of the laser drive signal and the enable signal, the red light-emitting module, the green light-emitting module, and the blue light-emitting module may be controlled to emit light alternately by using the drive unit, the current regulation unit, and the first switch assembly, and light-emitting durations of different light-emitting modules can be controlled by controlling the length of the duty timing. It should be understood that the lighting sequence of the laser light sources of different colors can be changed according to actual needs, which is not limited by the present application.

In some embodiments, by controlling the timing of the drive signal and the enable signal, the drive unit, the current regulation unit, and the second switch assembly are used to control the laser device Laser2 not to receive the drive current, and the laser device Laser1 emits light. In some embodiments, the drive units and current regulation units corresponding to two or more colors may also be controlled to operate simultaneously, and two or more laser light sources corresponding to two or more colors in the laser device Laser1 may be controlled to emit light simultaneously, thereby realizing the overlap function of the light source system.

In this embodiment, taking a tricolor laser device as an example, compared with the laser device parallel connection scheme in the related art, the present application uses three channels of drive chips to drive two series-connected common-cathode or common-anode circuits by means of the common-cathode or common-anode series connection method, saving at least three drive chips (constant current ICs), three energy storage inductors, three groups of current sampling resistors, three diodes, and peripheral circuits of the above components, further realizing the miniaturization of the light source system, and realizing the overlap function through timing control. In addition, under the condition that one laser device laser2 is faulty, the present application can perform image display through the laser device laser1. In addition, only the three MOSFETs M1-M3 in the present application are in the high-speed switching stage, which reduces EMC radiation and electromagnetic radiation problems.

Finally it is should be noted that: the above embodiments are only used to illustrate the technical solution of the present application, not to limit it; although the present application has been illustrated in detail by referring to the aforementioned embodiments, those of ordinary skill in the art should understood that: they can still can make modification to the technical solution recorded in each foregoing embodiment, or make equivalent replacement to part of or all the technical features thereof, but these modifications or replacements does not make the nature of the corresponding technical solution departing from the scope of the technical solution of each embodiment of the present application.

For the convenience of explanation, the foregoing description has been made in conjunction with specific embodiments. However, the above exemplary discussions are not intended to be exhaustive or to limit the embodiments to the specific forms disclosed above. Based on the above teachings, various modifications and variations can be derived. The selection and description of the above embodiments are intended to better explain the principles and practical applications, thereby enabling those skilled in the art to better use the embodiments and various modified embodiments suitable for specific usage considerations.

What is claimed is:

1. A light source system, comprising a power board, a display board, a laser device drive board, and a laser device module;
wherein the power board is configured to supply power to the display board and the laser device drive board, the display board comprises a display control circuit; the laser device drive board comprises at least one laser drive chip, the laser device module comprises at least one laser device;
wherein the display control circuit is configured to generate an enable signal and a laser drive signal based on image signals to be displayed, wherein the laser drive signal is an initial current control signal; and
the at least one laser drive chip is configured to receive the enable signal and the initial current control signal; and output a simulated constant current signal to the at least one laser device, so as to turn on the at least one laser device.

2. The light source system according to claim 1, wherein the enable signal comprises a timing control signal configured to coordinate light output timing for different emission colors; and the initial current control signal comprises a Pulse Width Modulation signal configured to control a brightness of the at least one laser device.

3. The light source system according to claim 1, further comprising a feedback compensation module, wherein:
a first end of the feedback compensation module is connected to the at least one laser device, and a second end of the feedback compensation module is connected to the at least one laser drive chip; and
the feedback compensation module is configured to filter a drive current corresponding to an abnormal signal in the laser drive signal to obtain a laser device feedback signal, and to output the laser device feedback signal to the at least one laser drive chip; and the at least one laser drive chip is configured to adjust a magnitude of the drive current based on the laser device feedback signal and the laser drive signal.

4. The light source system according to claim 3, wherein the feedback compensation module comprises a filtering unit; and an amplifying unit; wherein a first end of the amplifying unit is connected to the at least one laser device, a second end of the amplifying unit is connected to a first end of the filtering unit and the at least one laser drive chip, and a second end of the filtering unit is grounded; and
the amplifying unit is configured to convert the drive current flowing through the at least one laser device into a voltage signal, to amplify the voltage signal, and output the amplified voltage signal to the filtering unit; the filtering unit is configured to filter the drive current corresponding to the abnormal signal based on the amplified voltage signal to obtain the laser device feedback signal.

5. The light source system according to claim 4, wherein the amplifying unit comprises a transconductance amplifier;
wherein a first end of the transconductance amplifier is connected to a cathode of the at least one laser device, and a second end of the transconductance amplifier is connected to the first end of the filtering unit and a feedback signal detection end of the at least one laser drive chip;
wherein the filtering unit comprises a first filtering subunit and a second filtering subunit; a first end of the first filtering subunit, a first end of the second filtering subunit, and the second end of the amplifying unit are all connected to the feedback signal detection end; a second end of the first filtering subunit and a second end of the second filtering subunit are both grounded; and
wherein the first filtering subunit is configured to filter the drive current corresponding to the abnormal signal with a frequency less than or equal to a first frequency among abnormal signals; the second filtering subunit is configured to filter the drive current corresponding to the abnormal signal with a frequency greater than the first frequency and less than or equal to a second frequency among the abnormal signals.

6. The light source system according to claim 1, wherein the display control circuit comprises a display control unit and a selector switch unit;
wherein a first signal output end of the display control unit is connected to a first signal input end of the selector switch unit; an enable signal output end of the display control unit is connected to an enable signal input end of the selector switch unit and an enable signal receiving end of the at least one laser drive chip; and a selection signal output end of the selector switch unit is connected to a drive signal receiving end of the at least one laser drive chip;
when the laser device module comprises one laser device, the display control unit is configured to determine a plurality of channels of dimming analog signals based on a video signal to be displayed, and output the plurality of channels of dimming analog signals and a third enable signal to the selector switch unit; the selector switch unit, in response to the third enable signal, synthesizes the plurality of channels of dimming analog signals to obtain one channel of the laser drive signal;
or,
when the laser device module comprises one laser device, the display control unit is configured to determine a plurality of channels of dimming digital signals based on a video signal to be displayed, and output the plurality of channels of dimming digital signals and a third enable signal to the selector switch unit; the selector switch unit, in response to the third enable signal, synthesizes the plurality of channels of dimming digital signals to obtain one channel of the laser drive signal.

7. The light source system according to claim 1, wherein the laser device module comprises at least two laser devices, and the at least two laser devices are arranged in series; and
the light source system further comprises at least one first switch assembly, and the at least two laser devices are connected by means of the at least one first switch assembly;
wherein the at least two laser devices are all common-cathode laser devices or common-anode laser devices;
wherein the at least one first switch assembly is located inside the laser device module, and the at least one laser drive chip comprises at least two constant current assemblies;
wherein the display control circuit is connected to the at least two constant current assemblies, respectively, and is configured to output at least one channel of the laser drive signal and at least one channel of a first enable signal to the at least two constant current assemblies; the at least two constant current assemblies are configured to drive the at least two laser devices to emit light based on the laser drive signal when the received first enable signal is at an effective potential; and
wherein the display control circuit is connected to the at least one first switch assembly, and is configured to output a second enable signal to the at least one first switch assembly; the at least one first switch assembly is configured to turn on the at least two laser devices when the received second enable signal is at an effective potential;
wherein each of the at least two laser devices comprises at least two laser light sources corresponding to different colors; laser light sources of the same color among all the laser devices are sequentially connected in series to one of the at least two constant current assemblies, and one of the first switch assemblies is disposed between every two adjacent laser light sources.

8. The light source system according to claim 7, wherein each of the at least two constant current assemblies comprises a constant current chip, a voltage regulation assembly, and a first sampling resistor; the display control circuit is connected to the constant current chips in the at least two constant current assemblies, respectively; the constant current chip is connected to the voltage regulation assembly, the constant current chip and the voltage regulation assembly are connected to one end of the first sampling resistor, the other end of the first sampling resistor is grounded, and the voltage regulation assembly is connected to the laser device module.

9. The light source system according to claim 8, wherein the display control circuit determines a laser operating period, a target first switch assembly among the at least one first switch assembly, and a target constant current assembly among the at least two constant current assemblies;
during the laser operating period, the display control circuit controls the second enable signal output to the target first switch assembly and the first enable signal output to the target constant current assembly to be at an effective potential;
when the received second enable signal is at an effective potential, the target first switch assembly turns on the two laser devices connected to the target first switch assembly; and
when the received first enable signal is at an effective potential, the target constant current assembly outputs the drive current to the laser device module based on the laser drive signal; the drive current flows through each laser device in the laser device module and the target first switch assembly and then flows back to the target constant current assembly, and each laser device emits light.

10. The light source system according to claim 7, wherein each of the at least two laser devices comprises laser light sources of i colors, and the laser light sources of i colors correspond to the same anode or the same cathode; i is an integer greater than or equal to 2;
the at least one first switch assembly and the at least one laser drive chip are located in one driving device;
the display control circuit is configured to output first enable signals corresponding to the i colors to the at least one laser drive chip, and output second enable signals corresponding to the i colors to the at least one first switch assembly; and
for any one of the i colors, the at least one laser drive chip is configured to output the drive current to the laser light sources of the color when the first enable signals corresponding to the color are at a target value; the first switch assembly is configured to turn on the laser light sources of the color when the second enable signals corresponding to the color are at the target value, so that the laser light sources of the color receive the drive current to be turned on.

11. The light source system according to claim 10, wherein the driving device further comprises a second switch assembly; the display control circuit is further configured to output a third enable signal to the second switch assembly; the second switch assembly is turned on when the third enable signal is at a second value, so that the laser light sources in at least one target laser device among the at least two laser devices do not receive the drive current.

12. The light source system according to claim 11, wherein the display control circuit is further configured to:
receive an instruction to convert a brightness level into a target brightness level; and
in response to the instruction, output the third enable signal being at the second value to the second switch assembly;
or,
wherein the display control circuit is further configured to:
receive a laser light source fault notification from the at least one laser drive chip; and
in response to the laser light source fault notification, output the third enable signal being at the second value to the second switch assembly.

13. The light source system according to claim 12, wherein two laser devices are provided, and i is greater than 2; the at least one laser drive chip comprises i drive units in one-to-one correspondence with the i colors; after the second switch assembly is turned on, the display control circuit is further configured to:
if receiving a laser light source fault-free notification from a target drive unit, determine that the laser light source of the color corresponding to the target drive unit in a target laser device is faulty, and continue to output the third enable signal being at the second value to the second switch assembly, so as to perform image display by means of the laser device among the at least two laser devices excluding the target laser device; and
if receiving a laser light source fault notification from the target drive unit, determine that the laser light source of the color corresponding to the target drive unit in the laser device among the at least two laser devices excluding the target laser device is faulty, and shut down the light source system.

14. The light source system according to claim 13, wherein two laser devices are provided, and i is greater than 2; a first end of the second switch assembly is connected to the display control circuit;
if the laser light sources of the i colors comprised in the two laser devices correspond to the same cathode, a second end of the second switch assembly is connected to cathodes of the laser light sources of the i colors comprised in the two laser devices excluding the target laser device; and a third end of the second switch assembly is connected to cathodes of the laser light sources of the i colors comprised in the target laser device;
or,
if the laser light sources of the i colors comprised in the two laser devices correspond to the same anode, a second end of the second switch assembly is connected to anodes of the laser light sources of the i colors comprised in the target laser device; and a third end of the second switch assembly is connected to cathodes of the laser light sources of the i colors comprised in the target laser device.

15. The light source system according to claim 10, wherein the at least one laser drive chip comprises i drive units in one-to-one correspondence with the i colors; the at least one first switch assembly comprises i first switch units in one-to-one correspondence with the i colors; and
for any one of the colors, among the at least two laser devices, the laser light sources of the color are connected by means of the first switch unit corresponding to the color to form a light-emitting module of the color; a first end of the drive unit corresponding to the color is connected to a first end of the light-emitting module, a second end of the drive unit corresponding to the color is connected to a second end of the light-emitting module; and the display control circuit is connected to the first switch unit and a third end of the drive unit.

16. The light source system according to claim 15, wherein the driving device further comprises a current regulation module; the current regulation module comprises i current regulation units in one-to-one correspondence with the i colors; for any one of the colors:
a first end of the drive unit corresponding to the color is connected to a first end of the current regulation unit corresponding to the color, and a second end of the current regulation unit is connected to the first end of the light-emitting module; a third end of the current regulation unit is connected to the second end of the light-emitting module; a fourth end of the current regulation unit is connected to a fourth end of the drive unit corresponding to the color; and
the drive unit is configured to control a magnitude of the drive current output by the current regulation unit to the light-emitting module based on the laser drive signal from the display control circuit;
wherein each of the current regulation units comprises an inductor, a diode, and a third switch assembly; a first end of the inductor is connected to both a first end of the drive unit corresponding to the color, and a cathode of the diode; a second end of the inductor is connected to the first end of the light-emitting module; a first end of the third switch assembly is connected to the second end of the light-emitting module and an anode of the diode; a second end of the third switch assembly is connected to a fourth end of the drive unit corresponding to the color;
wherein the driving device further comprises a sampling module; the sampling module comprises i second sampling resistors in one-to-one correspondence with the i colors; for any one of the colors:
a third end of the third switch assembly is grounded via the second sampling resistor corresponding to the color.

17. The light source system according to claim 7, wherein the at least two laser devices are common-cathode laser devices;
for a first laser device and a second laser device among the at least two laser devices connected in series, an anode of each laser light source in the second laser device is connected to a first end of the corresponding first switch assembly; and
the second ends of all the first switch assemblies connected to the second laser device are connected to a common cathode of the first laser device; wherein the light source system comprises the first switch assembly and the second switch assembly;
the anode of each laser light source in the second laser device is connected to the first end of the corresponding first switch assembly; and
the second ends of all the first switch assemblies connected to the second laser device are respectively connected to the common cathode of the first laser device and a first end of the second switch assembly; a second end of the second switch assembly is connected to a common cathode of the second laser device.

18. The light source system according to claim 7, wherein the at least two laser devices comprises a plurality of laser devices that are common-anode laser devices;
for a third laser device and a fourth laser device among the at least two laser devices connected in series, a cathode of each laser light source in the third laser device is connected to a first end of the corresponding first switch assembly; and
the second ends of all the first switch assemblies connected to the third laser device are connected to a common anode of the fourth laser device; wherein the light source system comprises the first switch assembly and the second switch assembly; the cathode of each laser light source in the third laser device is connected to the first end of the corresponding first switch assembly; and
the second ends of all the first switch assemblies connected to the third laser device are respectively connected to a common anode of the fourth laser device and the first end of the second switch assembly; the second end of the second switch assembly is connected to the cathode of each laser light source in the third laser device.

19. A laser projection device, comprising the light source system according to claim 1.

20. The laser projection device according to claim 19, wherein the laser projection device further comprises an optical engine system and a lens system; the light source system provides a laser beam, the laser beam is transmitted to the optical engine system, the optical engine system modulates the laser beam and then transmits the modulated laser beam to the lens system, and the lens system projects the modulated laser beam onto a projection screen to achieve image display.
